(19) United States
(12) Patent Application Publication
(10) Pub. No.: US 2025/0331294 A1
(43) Pub. Date: Oct. 23, 2025

(54) INTEGRATED CIRCUIT DEVICES INCLUDING MULTI-GATE MOSFET

(71) Applicant: Samsung Electronics Co., Ltd., Suwon-si (KR)

(72) Inventors: YOUNGJIN YANG, Suwon-si (KR); KYOUNGMI PARK, Suwon-si (KR); KYUNAM PARK, Suwon-si (KR); WOOSEOK PARK, Suwon-si (KR); NAMHYUN LEE, Suwon-si (KR); DONGHOON HWANG, Suwon-si (KR)

(21) Appl. No.: 19/002,907

(22) Filed: Dec. 27, 2024

(30) Foreign Application Priority Data
Apr. 17, 2024 (KR) 10-2024-0051342

(51) Int. Cl. H10D 84/83; H10D 62/10; H10D 64/27; H10D 84/01

(52) U.S. Cl. CPC H10D 84/833; H10D 62/115; H10D 64/518; H10D 84/0151

(57) ABSTRACT

An IC device comprising: a substrate comprising fin-type active areas spaced apart from each other with a separation recess therebetween in a first direction and protruding in a second direction; a sheet separation wall comprising a lower sheet separation wall and an upper sheet separation wall thereon, the sheet separation wall extending in a third direction along the separation recess; a sheet barrier pattern on a lower surface and/or at least a portion of a side surface of the upper sheet separation wall; nanosheet stacked structures on the fin-type active areas and spaced apart from each other in the first direction with the sheet separation wall therebetween, each of the nanosheet stacked structures comprising nanosheets; a gate electrode on the fin-type active areas and the nanosheet stacked structures; indent spacers between the nanosheets and the sheet separation wall; and spacer layers between the gate electrode and the sheet separation wall.

### CROSS-REFERENCE TO RELATED APPLICATIONS

This application is based on and claims priority under 35 U.S.C. § 119 to Korean Patent Application No. 10-2024-0051342, filed on Apr. 17, 2024, in the Korean Intellectual Property Office, the disclosure of which is incorporated by reference herein in its entirety.

### BACKGROUND OF THE INVENTION

The inventive concept relates to integrated circuit devices, and more particularly, to integrated circuit devices including a multi-gate Metal-Oxide-Semiconductor Field-Effect Transistor (MOSFET).

As the degree of integration of integrated circuit devices has increased, a device size has decreased close to a minimum state, and scaling of devices has reached close to a limit. Therefore, in order to improve the performance of devices, it may be needed to develop a new method through a change in a structure of devices, and thus, integrated circuit devices including a transistor having a new structure such as a multi-gate MOSFET have been proposed.

### SUMMARY OF THE INVENTION

The inventive concept provides integrated circuit devices including a multi-gate Metal-Oxide-Semiconductor Field-Effect Transistor (MOSFET) with improved operational characteristics.

According to an aspect of the inventive concepts, an integrated circuit device comprising: a base substrate layer comprising a pair of fin-type active areas spaced apart from each other with a separation recess therebetween in a first direction and protruding in a second direction; a sheet separation wall comprising a lower sheet separation wall and an upper sheet separation wall on the lower sheet separation wall, the sheet separation wall extending in a third direction along the separation recess; a sheet barrier pattern on a lower surface and/or at least a portion of a side surface of the upper sheet separation wall; a pair of nanosheet stacked structures on the pair of fin-type active areas and spaced apart from each other in the first direction with the separation recess and the sheet separation wall therebetween, each of the pair of nanosheet stacked structures comprising a plurality of nanosheets; a gate electrode on the pair of fin-type active areas and the pair of nanosheet stacked structures and extending in the first direction; a plurality of indent spacers between the plurality of nanosheets and the sheet separation wall; and a plurality of spacer layers between the gate electrode and the sheet separation wall, wherein the first direction is parallel with a lower surface of the base substrate layer, wherein the second direction is perpendicular to the lower surface of the base substrate layer, and wherein the third direction is parallel with the lower surface of the base substrate layer and intersects with the first direction.

According to another aspect of the inventive concepts, an integrated circuit device comprising: a base substrate layer comprising a pair of fin-type active areas spaced apart from each other with a separation recess therebetween in a first direction and protruding in a second direction; a sheet separation wall extending in a third direction along the separation recess and comprising a lower sheet separation wall and an upper sheet separation wall on the lower sheet separation wall, wherein a width of the lower sheet separation wall is greater than a width of the upper sheet separation wall in the first direction; a sheet barrier pattern between a lower surface of the upper sheet separation wall and an upper surface of the lower sheet separation wall; a pair of nanosheet stacked structures on the pair of fin-type active areas and spaced apart from each other in the first direction with the separation recess and the sheet separation wall therebetween, each of the pair of nanosheet stacked structures comprising a plurality of nanosheets; a pair of source/drain regions on the pair of fin-type active areas and electrically connected to the plurality of nanosheets included in the pair of nanosheet stacked structures; a gate electrode on the pair of fin-type active areas and the pair of nanosheet stacked structures and extending in the first direction; a plurality of indent spacers between the plurality of nanosheets and the sheet separation wall; and a plurality of spacer layers between the gate electrode and the sheet separation wall, wherein the first direction is parallel with a lower surface of the base substrate layer, wherein the second direction is perpendicular to the lower surface of the base substrate layer, and wherein the third direction is parallel with the lower surface of the base substrate layer and intersects with the first direction.

According to another aspect of the inventive concepts, an integrated circuit device comprising: a base substrate layer comprising a pair of fin-type active areas spaced apart from each other with a separation recess therebetween in a first direction and protruding in a second direction; a sheet separation wall comprising a lower sheet separation wall and an upper sheet separation wall on the lower sheet separation wall, wherein the lower sheet separation wall and the upper sheet separation wall is spaced apart from each other in the second direction, and the sheet separation wall extends in a third direction along the separation recess; a sheet barrier pattern on a lower surface and a side surface of the upper sheet separation wall and comprising a material different from a material in the sheet separation wall; a pair of nanosheet stacked structures on the pair of fin-type active areas and spaced apart from each other in the first direction with the separation recess and the sheet separation wall therebetween, each of the pair of nanosheet stacked structures comprising a plurality of nanosheets; source/drain regions on the pair of fin-type active areas and electrically connected to the plurality of nanosheets included in the pair of nanosheet stacked structures; a gate electrode on the pair of fin-type active areas and the pair of nanosheet stacked structures and extending in the first direction; a gate insulating layer between the gate electrode and the plurality of nanosheets included in the pair of nanosheet stacked structures and between the gate electrode and the pair of fin-type active areas; a plurality of indent spacers between the plurality of nanosheets and the sheet separation wall; and a plurality of spacer layers between the gate electrode and the sheet separation wall, wherein a thickness of each of the plurality of spacer layers on a side surface of the sheet separation wall in the first direction is less than a thickness of each of the plurality of indent spacers in the first direction, wherein, in the first direction, a width of the upper sheet separation wall is less than a width of the lower sheet separation wall, wherein the first direction is parallel with a lower surface of the base substrate layer, wherein the second direction is perpendicular to the lower surface of the base substrate layer, and wherein the third direction is parallel with the lower surface of the base substrate layer and intersects with the first direction.

### BRIEF DESCRIPTION OF THE DRAWINGS

Embodiments will be more clearly understood from the following detailed description taken in conjunction with the accompanying drawings in which:

FIG. 1 is a layout illustrating an integrated circuit device, according to some embodiments;

FIGS. 2A, 2B, 2C, 2D, 2E, 2F, 2G, 2H, 2I, 2J, 2K, 2L, 2M, 2N, 2O, 2P, 2Q, 2R, 2S, 2T, and 2U, 3A, 3B, and 3C, 4A and 4B, 5A and 5B, 6A and 6B, 7A and 7B, 8A and 8B, 9A and 9B, 10A and 10B, 11A and 11B, 12A and 12B, 13A and 13B, and 14A and 14B are vertical cross-sectional views and perspective views for describing a method of manufacturing an integrated circuit device, according to some embodiments;

FIGS. 15A, 15B, 15C, and 15D are vertical cross-sectional views illustrating an integrated circuit device, according to some embodiments;

FIGS. 16A, 16B, 16C, 16D, 16E, 16F, and 16G are vertical cross-sectional views for describing a method of manufacturing an integrated circuit device, according to some embodiments;

FIG. 17 is a vertical cross-sectional view illustrating an integrated circuit device, according to some embodiments;

FIGS. 18A, 18B, 18C, 18D, 18E, 18F, and 18G are vertical cross-sectional views for describing a method of manufacturing an integrated circuit device, according to some embodiments;

FIG. 19 is a vertical cross-sectional view illustrating an integrated circuit device, according to some embodiments;

FIGS. 20A and 20B and 21A and 21B are vertical cross-sectional views illustrating an integrated circuit device, according to some embodiments; and

FIGS. 22 and 23 are vertical cross-sectional views illustrating an integrated circuit device, according to some embodiments.

### DETAILED DESCRIPTION OF THE INVENTION

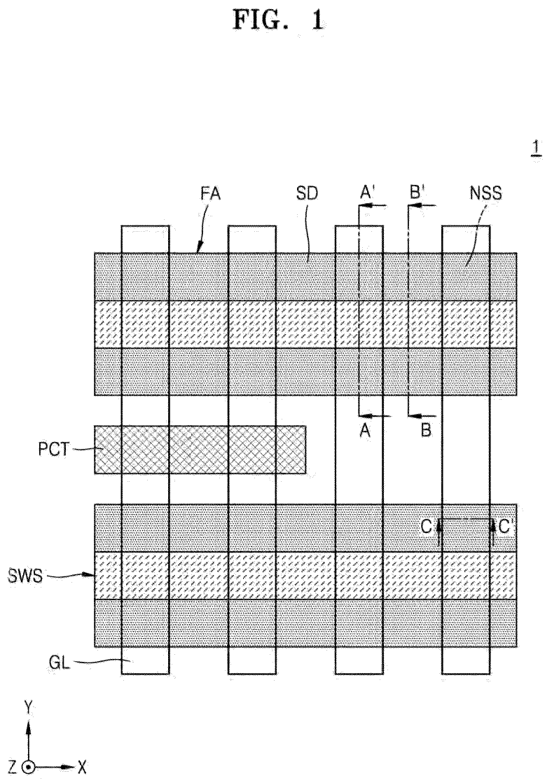

FIG. 1 is a layout illustrating an integrated circuit device, according to some embodiments.

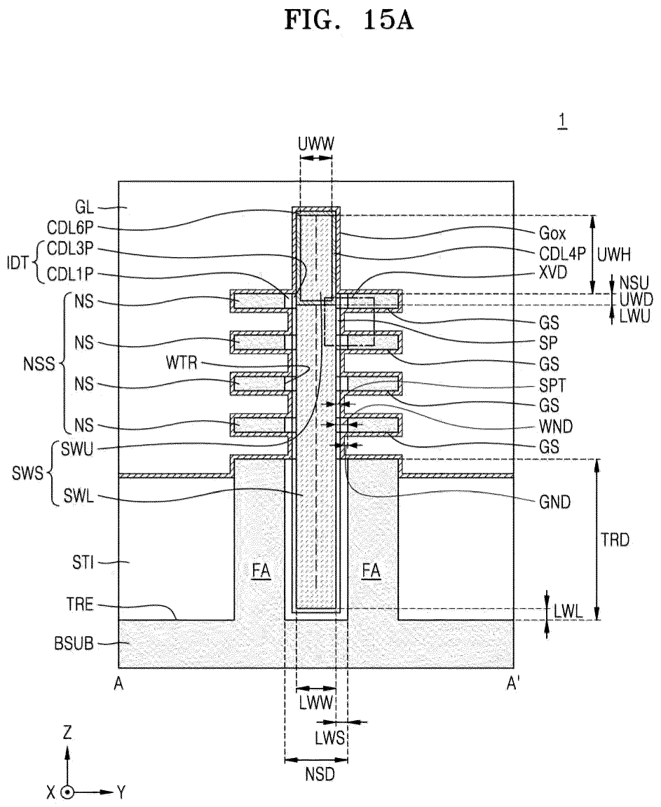

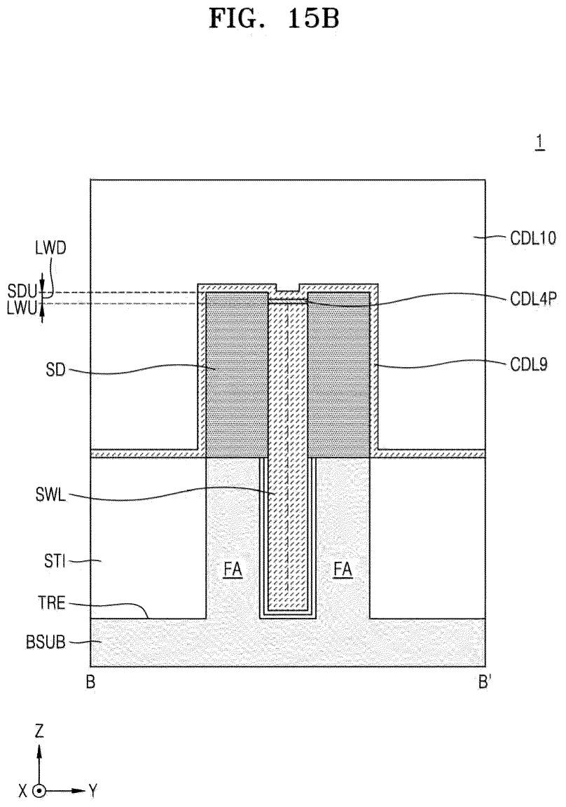

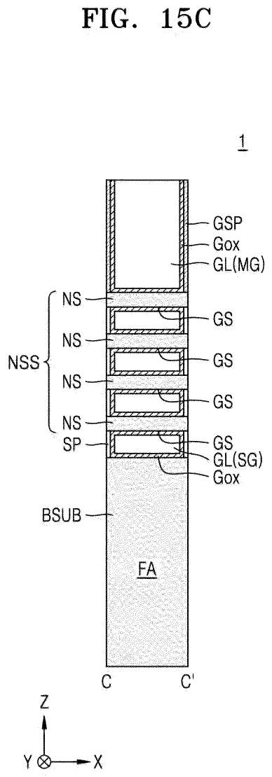

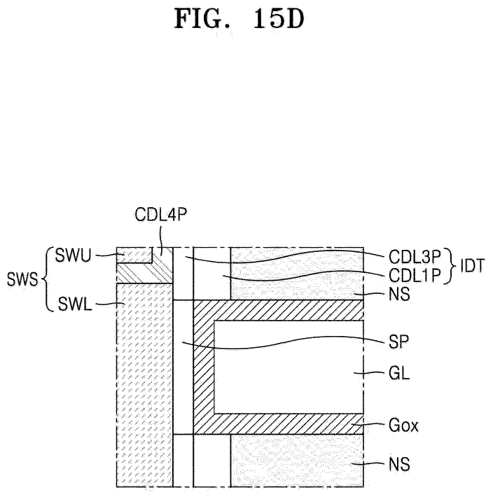

Referring to FIG. 1, an integrated circuit device 1 may include a plurality of sheet separation walls SWS extending along (in) a first horizontal direction (e.g., X direction), a plurality of fin-type active areas FA, a plurality of gate electrodes GL extending along (in) a second horizontal direction (e.g., Y direction), and at least one gate cut structure PCT extending along (in) the first horizontal direction (e.g., X direction) and cutting across at least some (at least one) of the plurality of gate electrodes GL. The first horizontal direction (e.g., X direction) and the second horizontal direction (e.g., Y direction) may intersect (e.g., may be perpendicular to) each other. A plurality of nanosheet stacked structures NSS may be located at intersections between the plurality of fin-type active areas FA and the plurality of gate electrodes GL. Each of the plurality of nanosheet stacked structures NSS may include a plurality of nanosheets NS (see FIGS. 15A and 15C) stacked to be spaced apart from each other in a vertical direction (e.g., Z direction). A source/drain region SD may be located on the fin-type active area FA between a pair of nanosheet stacked structures NSS adjacent to each other in the first horizontal direction (e.g., X direction) from among the plurality of nanosheet stacked structures NSS. For example, the plurality of nanosheet stacked structures NSS and a plurality of source/drain regions SD may be alternately located along (in) the first horizontal direction (e.g., X direction) on the plurality of fin-type active areas FA. For example, the first horizontal direction and the second horizontal direction may be parallel with an upper surface and/or a lower surface of a base substrate layer BSUB (to be described later), and the vertical direction may be perpendicular to the upper surface and/or the lower surface of the base substrate layer BSUB. As used herein, the term “and/or” includes any and all combinations of one or more of the associated listed items. Expressions such as “at least one of,” when preceding a list of elements, modify the entire list of elements and do not modify the individual elements of the list.

The plurality of nanosheet stacked structures NSS may be arranged in rows and columns along (in) the first horizontal direction (e.g., X direction) and the second horizontal direction (e.g., Y direction). The plurality of nanosheet stacked structures NSS may be adjacent to the plurality of sheet separation walls SWS and may be arranged in columns along (in) the first horizontal direction (e.g., X direction). A pair of nanosheet stacked structures NSS corresponding to each other from among the plurality of nanosheet stacked structures NSS may be spaced apart from each other in the second horizontal direction (e.g., Y direction) with the sheet separation wall SWS therebetween.

The integrated circuit device 1 may include a plurality of logic cells. Each of the logic cells may include a plurality of circuit elements such as a transistor and a register and may be configured in various ways. The logic cell may include, for example, an AND, a NAND, an OR, a NOR, an exclusive OR (XOR), an exclusive NOR (XNOR), an inverter (INV), an adder (ADD), a buffer (BUF), a delay (DLY), a filter (FIL), a multiplexer (MXT/MXIT), an OR/AND/INVERTER (OAI), AND/OR (AO), an AND/OR/INVERTER (AOI), a D flip-flop, a reset flip-flop, a master-slaver flip-flop, and/or a latch, and the logic cell may configure a standard cell that performs a logical function.

The gate electrodes GL divided into two by the gate cut structure PCT may be spaced apart from each other in the second horizontal direction (e.g., Y direction) with the gate cut structure PCT therebetween.

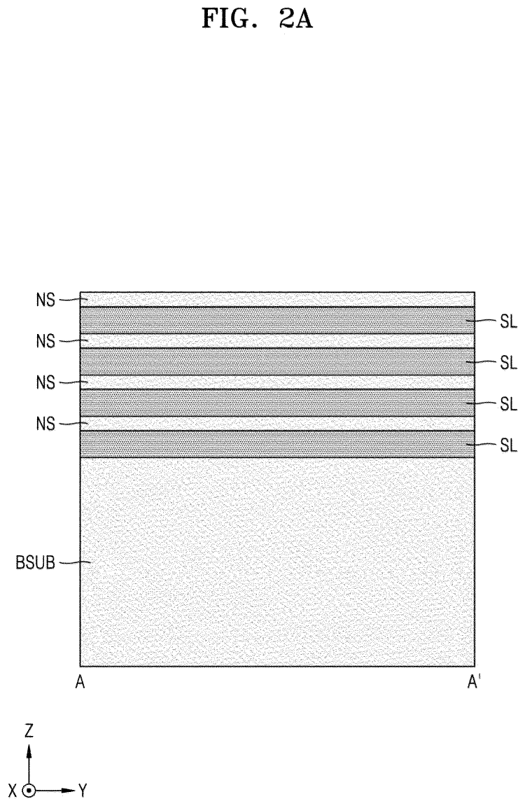

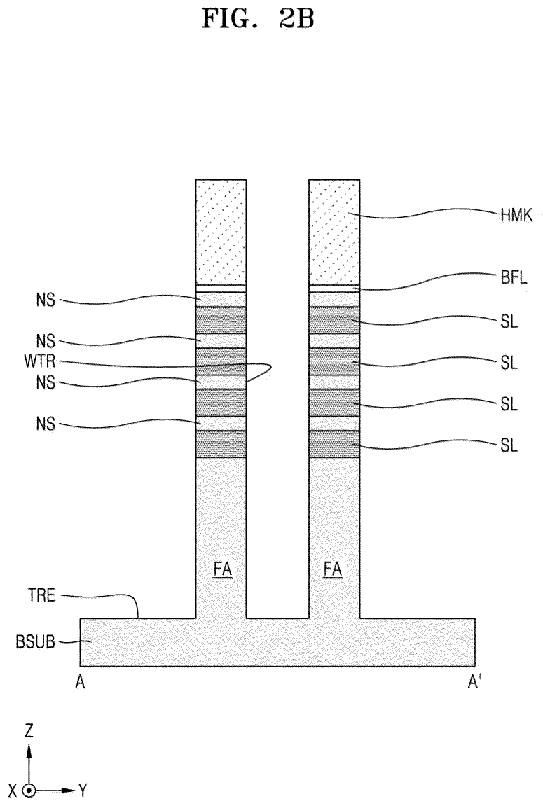

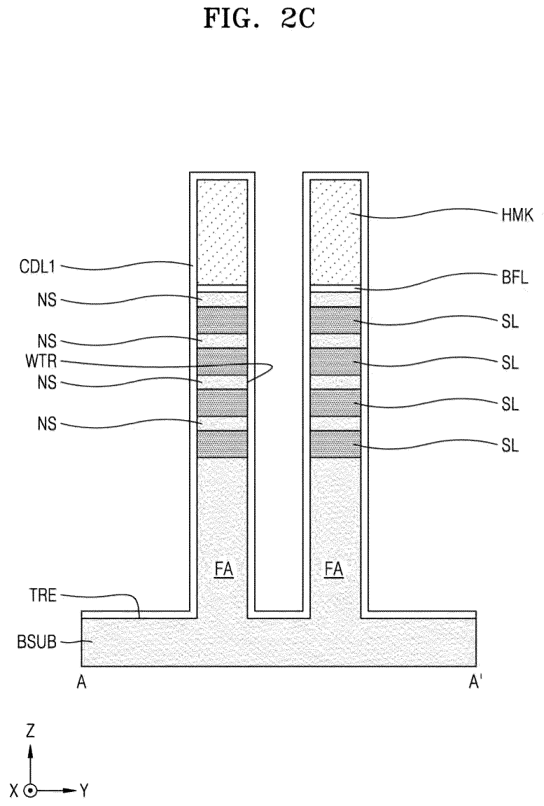

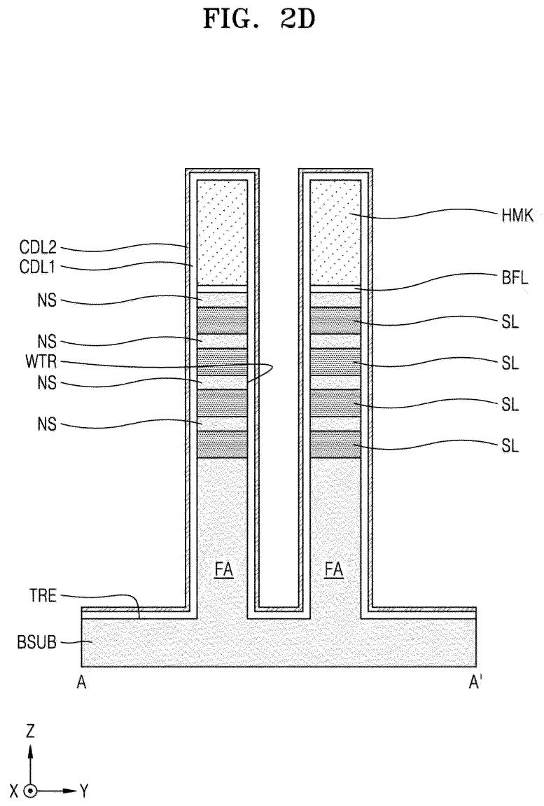

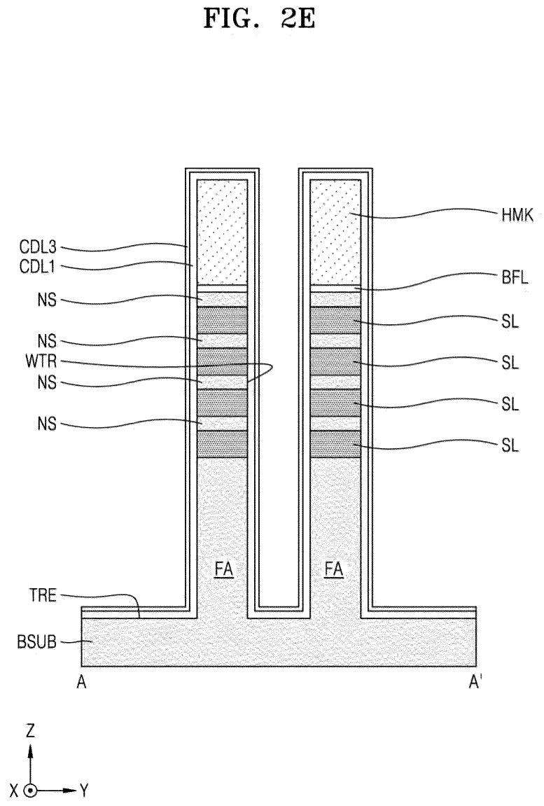

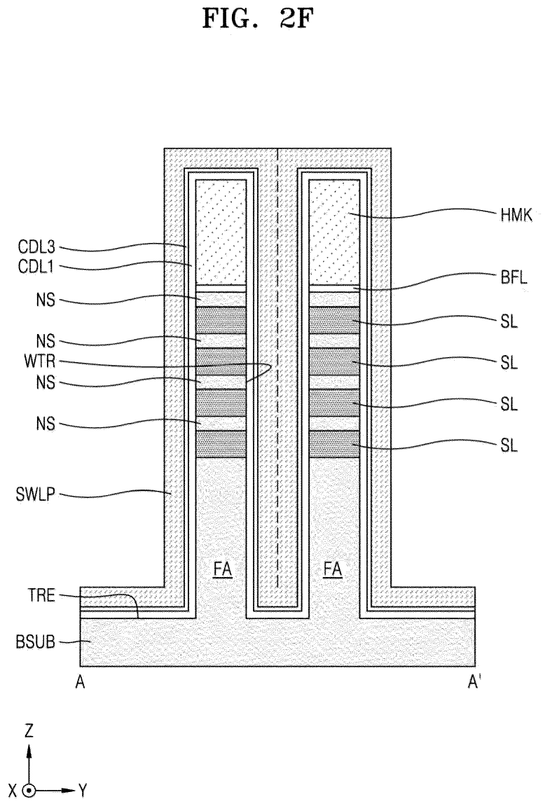

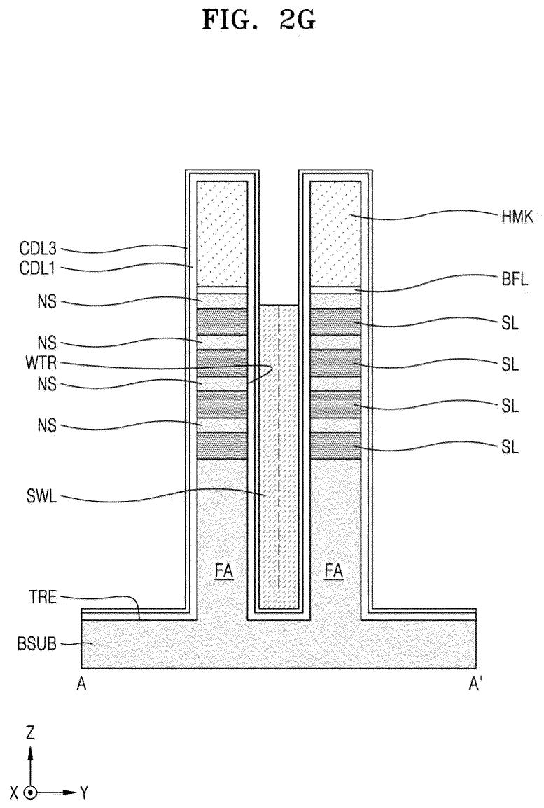

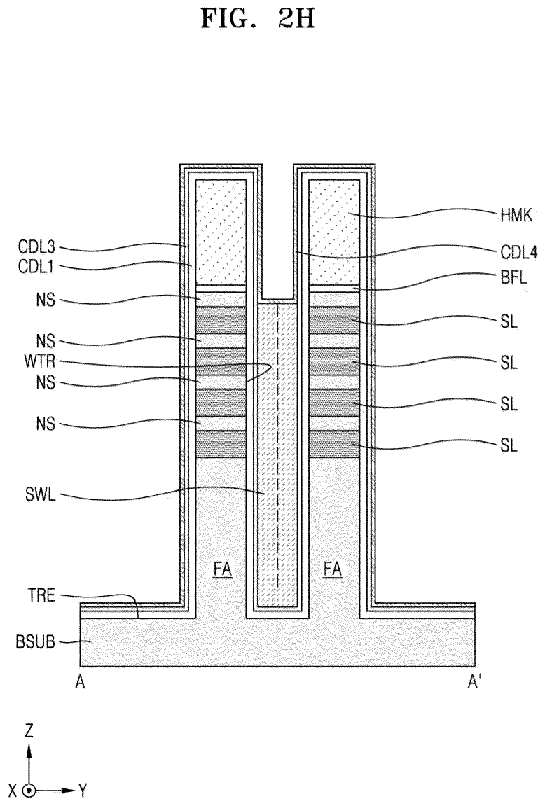

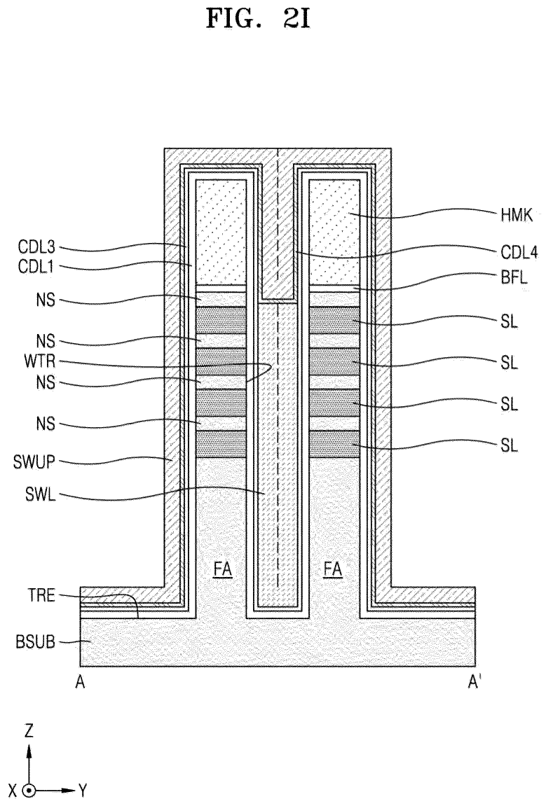

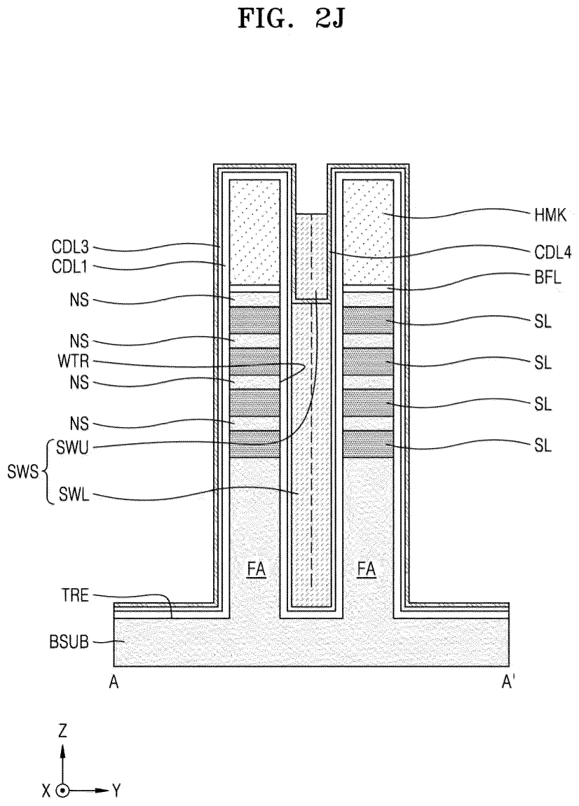

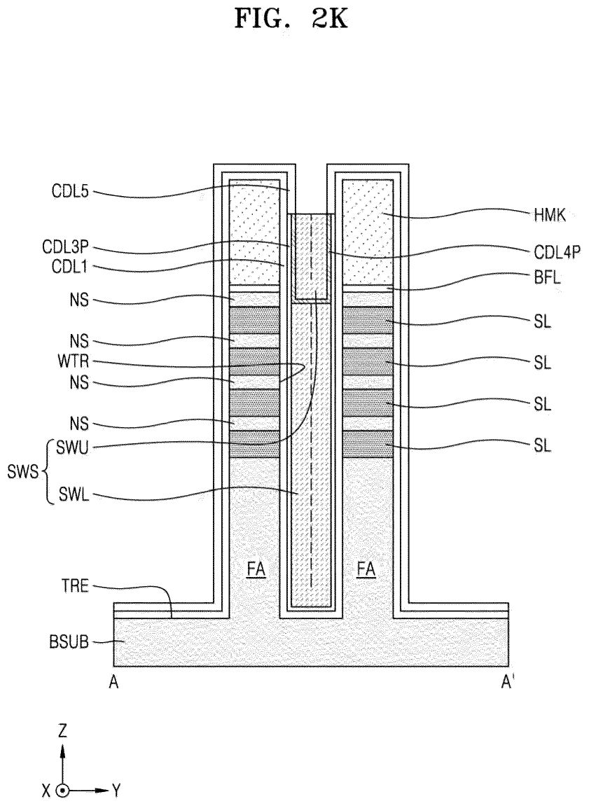

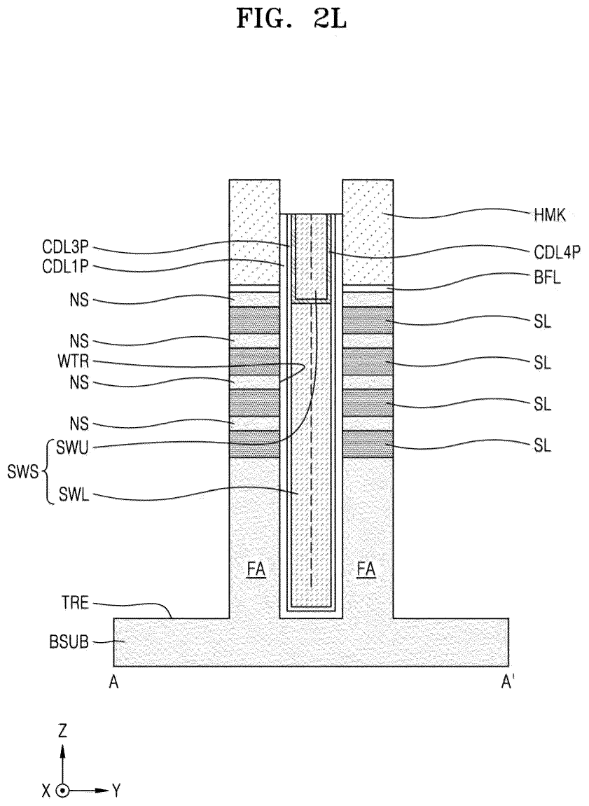

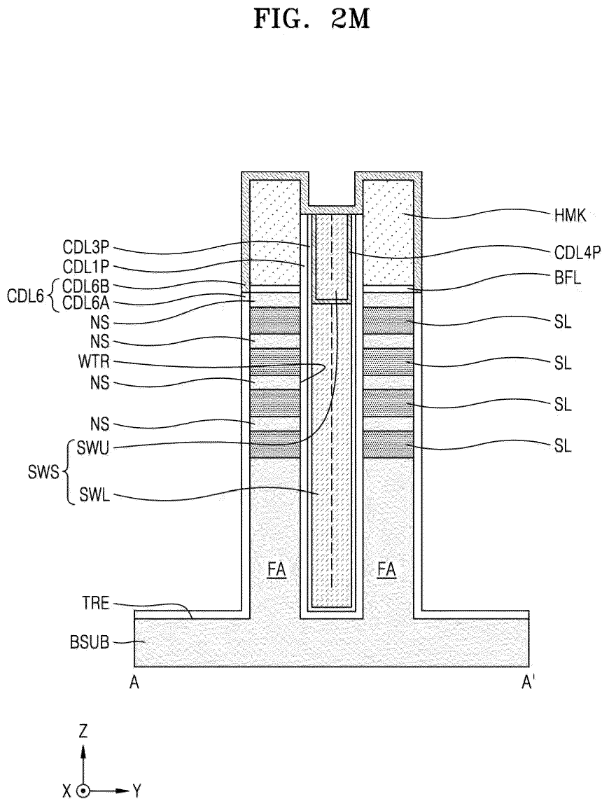

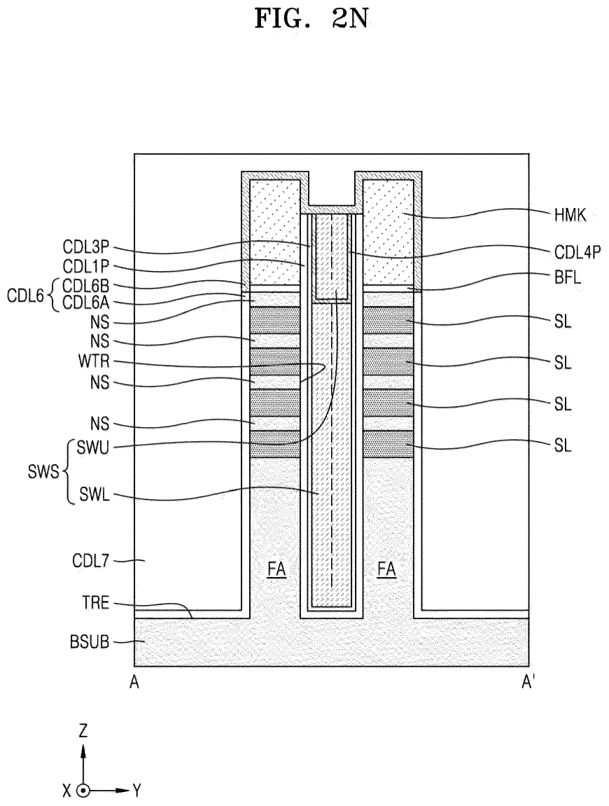

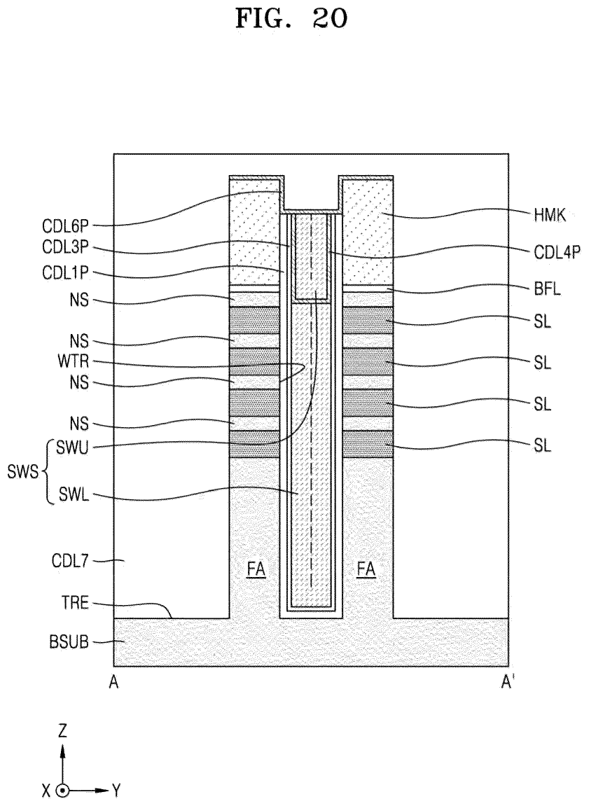

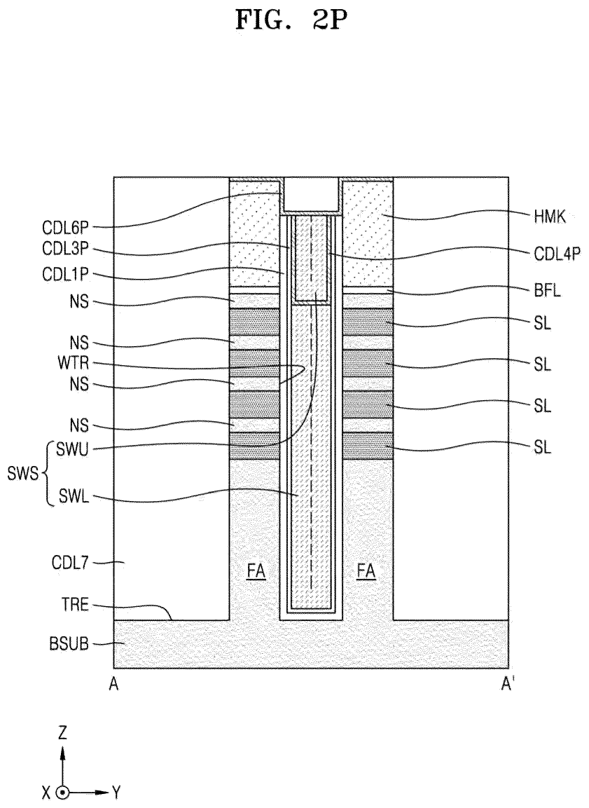

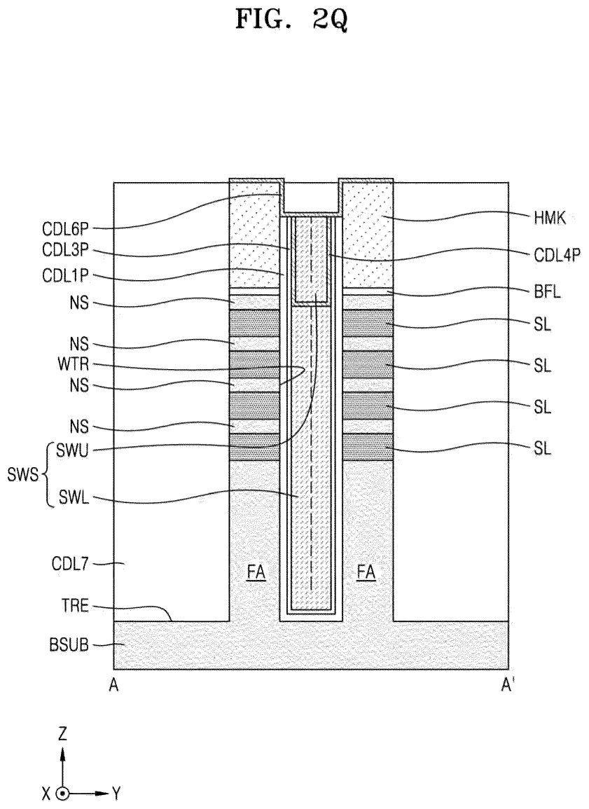

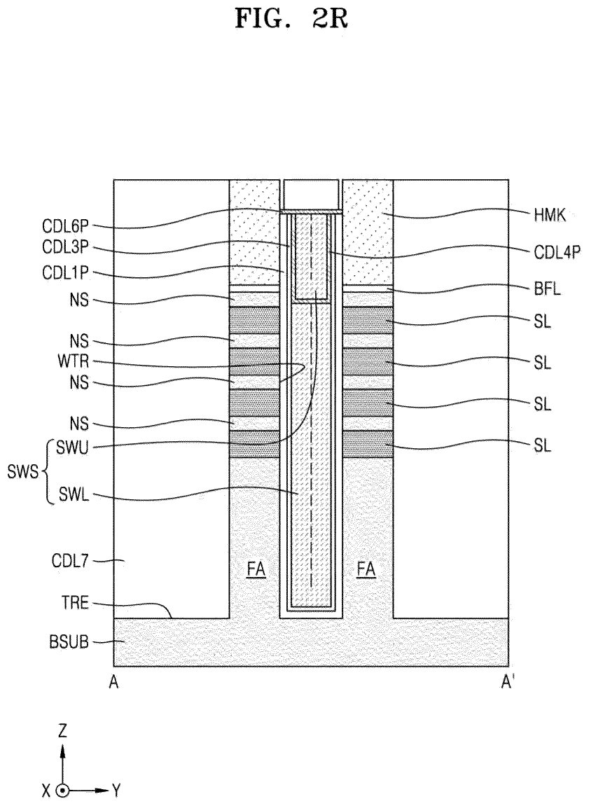

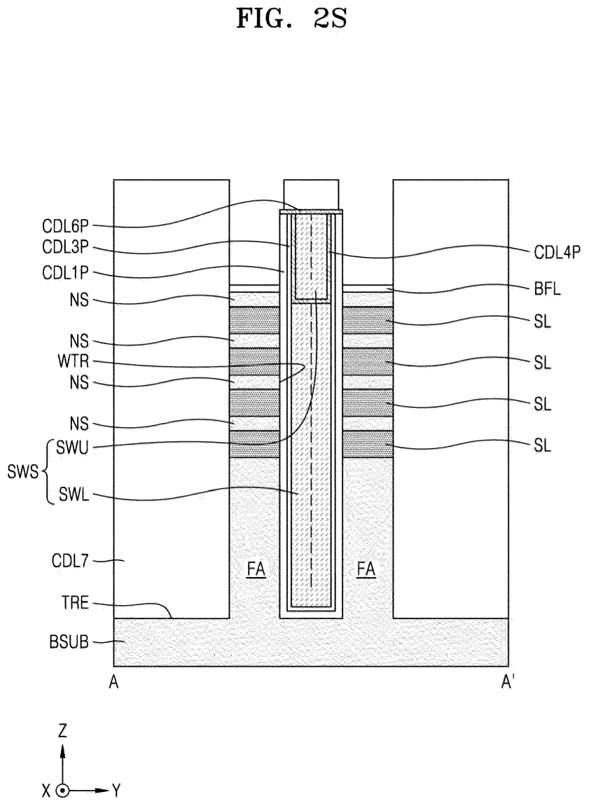

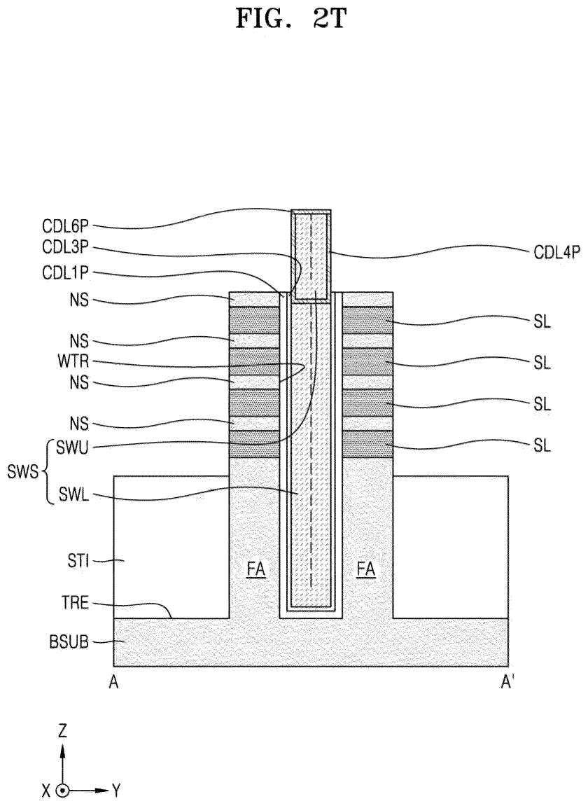

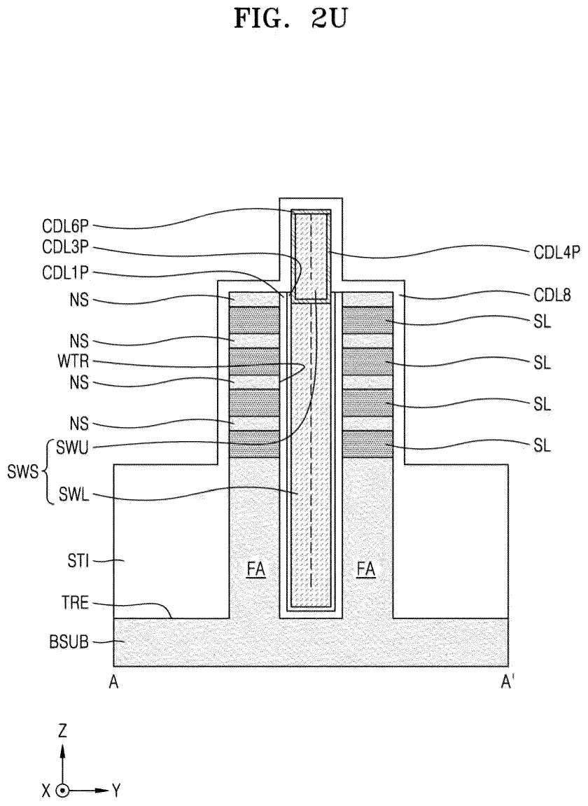

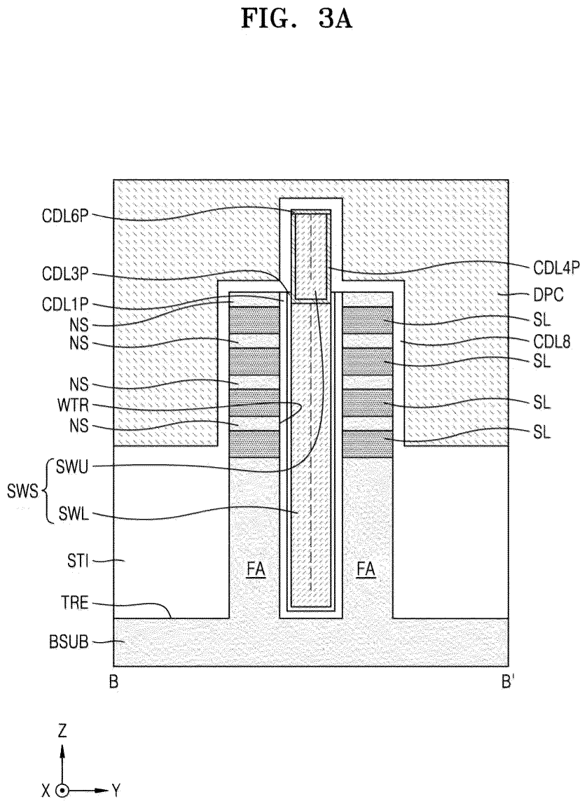

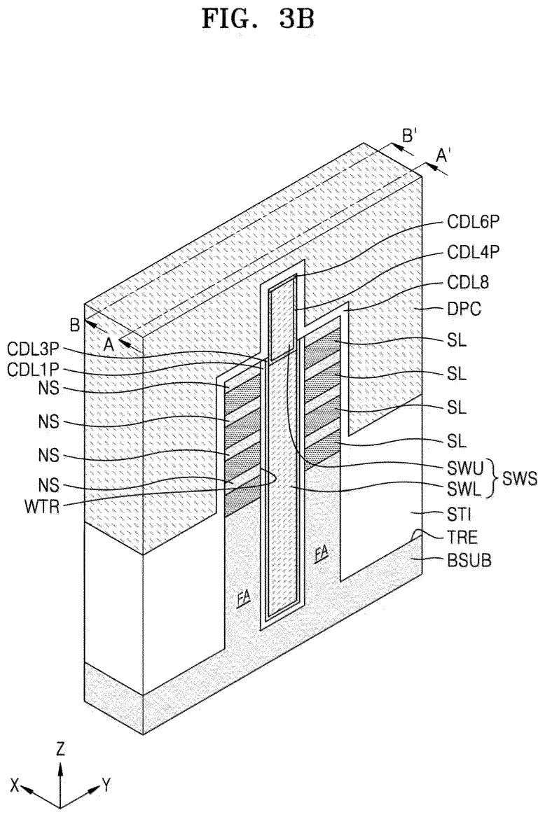

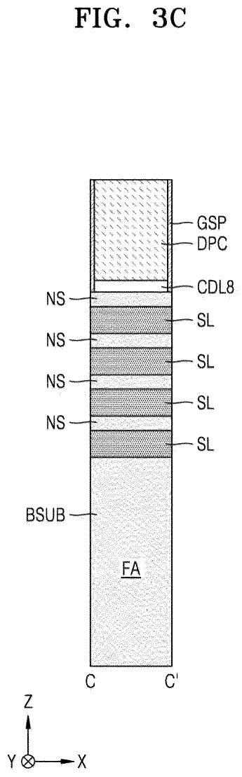

FIGS. 2A, 2B, 2C, 2D, 2E, 2F, 2G, 2H, 2I, 2J, 2K, 2L, 2M, 2N, 2O, 2P, 2Q, 2R, 2S, 2T, and 2U, 3A, 3B, and 3C, 4A and 4B, 5A and 5B, 6A and 6B, 7A and 7B, 8A and 8B, 9A and 9B, 10A and 10B, 11A and 11B, 12A and 12B, 13A and 13B, and 14A and 14B are vertical cross-sectional views and perspective views for describing a method of manufacturing an integrated circuit device, according to some embodiments. In detail, FIGS. 2A, 2B, 2C, 2D, 2E, 2F, 2G, 2H, 2I, 2J, 2K, 2L, 2M, 2N, 2O, 2P, 2Q, 2R, 2S, 2T, and 2U, 10A, 11A, 12A, 13A, and 14A are vertical cross-sectional views taken along line A-A′ of FIG. 1, FIGS. 3A, 4A, 5A, 6A, 7A, 8A, and 9A are vertical cross-sectional views taken along line B-B′ of FIG. 1, FIGS. 3C, 10B, 11B, 12B, 13B, and 14B are vertical cross-sectional views taken along line C-C′ of FIG. 1, and FIGS. 3B, 4B, 5B, 6B, 7B, 8B, and 9B are perspective views corresponding to FIGS. 3A, 4A, 5A, 6A, 7A, 8A, and 9A.

Referring to FIG. 2A, a plurality of sacrificial layers SL and a plurality of nanosheets NS may be alternately stacked layer-by-layer on the base substrate layer BSUB. Each of the plurality of sacrificial layers SL may be located between the base substrate layer BSUB and a lowermost nanosheet NS from among the plurality of nanosheets NS and between two nanosheets NS adjacent to each other along (in) the vertical direction (e.g., Z direction) from among the plurality of nanosheets NS. Each of the plurality of nanosheets NS and the plurality of sacrificial layers SL may extend parallel to the upper surface (e.g., a top surface) of the base substrate layer BSUB. In some embodiments, the plurality of nanosheets NS may be formed to have substantially the same thickness. Alternatively, in some embodiments, the lowermost nanosheet NS of the plurality of nanosheets NS may be thinner than the other nanosheets NS.

The base substrate layer BSUB may include, for example, a semiconductor material such as silicon (Si) and/or germanium (Ge), or a compound semiconductor material such as silicon germanium (SiGe), silicon carbide (SiC), gallium arsenide (GaAs), indium arsenide (InAs), and/or indium phosphide (InP). In some embodiments, the base substrate layer BSUB may include (e.g., may be formed of) a group III-V material and/or a group IV material. The group III-V material may be a binary, ternary, or quaternary compound semiconductor material including at least one group III element and at least one group V element. The base substrate layer BSUB may include a conductive region, for example, a well doped with impurities or a structure doped with impurities.

In some embodiments, the plurality of nanosheets NS may include (e.g., may be formed of) a material having etch characteristics that are the same as or similar to those of a material of the base substrate layer BSUB. The plurality of sacrificial layers SL may include (e.g., may be formed of) a material having an etch selectivity with respect to (the material of) the plurality of nanosheets NS. In some embodiments, each of the plurality of nanosheets NS and the base substrate layer BSUB may include a semiconductor material such as Si or Ge. In some embodiments, the plurality of sacrificial layers SL may include a compound semiconductor material such as SiGe. In some embodiments, each of the plurality of nanosheets NS, the base substrate layer BSUB, and the plurality of sacrificial layers SL may include a compound semiconductor material such as SiGe. A concentration of Ge atoms among Si atoms and Ge atoms included in each of the plurality of nanosheets NS and the base substrate layer BSUB may be different from a concentration of Ge atoms among Si atoms and Ge atoms included in each of the plurality of sacrificial layers SL.

Referring to FIG. 2B, a plurality of hard mask patterns HMK may be formed on a stacked structure of the plurality of sacrificial layers SL and the plurality of nanosheets NS, the plurality of nanosheets NS and the plurality of sacrificial layers SL may be patterned by using the plurality of hard mask patterns HMK as an etch mask, and a portion of the base substrate layer BSUB exposed between patterned resultant structures may also be removed to form a plurality of trenches TRE and a separation recess WTR. In some embodiments, a buffer layer BFL may be formed on a stacked structure of the plurality of sacrificial layers SL and the plurality of nanosheets NS, and then the plurality of hard mask patterns HMK may be formed on the buffer layer BFL. The buffer layer BFL, the plurality of nanosheets NS, and the plurality of sacrificial layers SL may be patterned by using the plurality of hard mask patterns HMK as an etch mask. In some embodiments, the buffer layer BFL may include (e.g., may be formed of) oxide.

A portion of the base substrate layer BSUB protruding from a lower surface (e.g., a bottom surface) of each of the plurality of trenches TRE and the lower separation recess WTR may be referred to as the fin-type active area FA. The lower separation recess WTR may refer to a portion of the lower separation recess WTR that is located lower than the lowermost sacrificial layer SL among the plurality of sacrificial layers SL (or the lowermost nanosheet NS among the plurality of nanosheets NS) in the vertical direction (e.g., Z direction). The vertical level may be a relative location (e.g., distance) from the lower surface of the base substrate layer BSUB in the vertical direction (e.g., Z direction). A farther distance from the lower surface of the base substrate layer BSUB may be a higher vertical level. A closer distance to the base substrate layer BSUB may be a lower vertical level.

The plurality of hard mask patterns HMK may extend in the first horizontal direction (e.g., X direction) and may be spaced apart from each other in the second horizontal direction (e.g., Y direction). The first horizontal direction (e.g., X direction) and the second horizontal direction (e.g., Y direction) may be perpendicular to each other. Each of the plurality of hard mask patterns HMK may include, for example, nitride. For example, each of the plurality of hard mask patterns HMK may include (e.g., may be formed of) silicon nitride.

Each of the plurality of trenches TRE and the lower separation recess WTR may extend in the first horizontal direction (e.g., X direction). In some embodiments, the plurality of trenches TRE and the plurality of lower separation recesses WTR may be alternately arranged along the second horizontal direction (e.g., Y direction). The plurality of trenches TRE may be formed so that a horizontal width of each of the plurality of trenches TRE in the second horizontal direction (e.g., Y direction) is greater than a horizontal width of each of the lower separation recesses WTR in the second horizontal direction (e.g., Y direction). In some embodiments, each of the plurality of trenches TRE and the lower separation recesses WTR may extend in the vertical direction (e.g., Z direction) and may have a tapered shape with an increasing horizontal width in the second horizontal direction (e.g., Y direction).

Referring to FIG. 2C, a first material layer CDL1 on (e.g., covering or overlapping) the plurality of hard mask patterns HMK, the plurality of buffer layers BFL, the plurality of nanosheets NS, the plurality of sacrificial layers SL, and the base substrate layer BSUB may be formed. The first material layer CDL1 may include (e.g., may be formed of) an insulating material. For example, the first material layer CDL1 may include (e.g., may be formed of) oxide. In some embodiments, the first material layer CDL1 may conformally cover exposed surfaces of the plurality of hard mask patterns HMK, the plurality of buffer layers BFL, the plurality of nanosheets NS, the plurality of sacrificial layers SL, and the base substrate layer BSUB and may not completely (entirely or fully) fill the plurality of trenches TRE and the separation recess WTR. The first material layer CDL1 may be in (may partially fill) the plurality of trenches TRE and the separation recess WTR. For example, the first material layer CDL1 may be formed by using thermal oxidation, atomic layer deposition (ALD), chemical vapor deposition (CVD), physical vapor deposition (PVD), metal organic ALD (MOALD), and/or metal organic CVD (MOCVD).

Referring to FIG. 2D, a second material layer CDL2 on (e.g., covering or overlapping) the first material layer CDL1 may be formed. The second material layer CDL2 may include (e.g., may be formed of) an insulating material. For example, the second material layer CDL2 may include (e.g., may be formed of) silicon carbonate (SiOC). In some embodiments, the second material layer CDL2 may conformally cover a surface of the first material layer CDL1 and may not completely (entirely or fully) fill the plurality of trenches TRE and the separation recess WTR. The second material layer CDL2 may be in (may partially fill) the plurality of trenches TRE and the separation recess WTR. For example, the second material layer CDL2 may be formed by using thermal oxidation, ALD, CVD, PVD, MOALD, and/or MOCVD.

Referring to FIGS. 2D and 2E, a physical property of the second material layer CDL2 may be changed to form a third material layer CDL3. For example, heat treatment may be performed on the second material layer CDL2 to change the physical property of the second material layer CDL2 to form the third material layer CDL3. The third material layer CDL3 may include (e.g., may be formed of) an insulating material. Although the first material layer CDL1 may be maintained and only the physical property of the second material layer CDL2 may be changed to form the third material layer CDL3 in FIGS. 2D and 2E, this is for convenience of illustration and the inventive concept is not limited thereto. While the physical property of the second material layer CDL2 is changed to form the third material layer CDL3, a physical property of the first material layer CDL1 may also be changed so that the first material layer CDL1 has characteristics similar to those of the third material layer CDL3. For example, some of carbon atoms included in the second material layer CDL2 may be diffused into the first material layer CDL1, and both (each of) the first material layer CDL1 and the third material layer CDL3 may include silicon carbonate with a carbon atom content lower than that of the second material layer CDL2.

Referring to FIG. 2F, a preliminary lower separation layer SWLP on (e.g., covering or overlapping) the third material layer CDL3 and filling the separation recess WTR may be formed. The preliminary lower separation layer SWLP may completely (entirely or fully) fill the separation recess WTR and may partially fill the plurality of trenches TRE. For example, the preliminary lower separation layer SWLP may have a thickness that is ½ (half) or more (more than half) of a horizontal distance between the adjacent (facing) third material layers CDL3 in the separation recess WTR in the second horizontal direction (e.g., Y direction). For example, the preliminary lower separation layer SWLP may include (may be formed of) silicon nitride.

Referring to FIGS. 2F and 2G together, a lower sheet separation wall SWL may be formed by removing a portion (e.g., an upper portion) of the preliminary lower separation layer SWLP. The lower sheet separation wall SWL may be in (e.g., may partially fill) the separation recess WTR. While the lower sheet separation wall SWL is formed, (all portions of) the preliminary lower separation layer SWLP in (filling) the plurality of trenches TRE may be removed. For example, the lower sheet separation wall SWL may fill (at least) a lower portion of the separation recess WTR and may not fill an upper portion of the separation recess WTR. An upper surface (e.g., an uppermost surface) of the lower sheet separation wall SWL may be located at a vertical level equal to or higher than that of a lower surface (e.g., a bottom surface) of an uppermost nanosheet NS from among the plurality of nanosheets NS and lower than that of an upper surface (e.g., a top surface) of the uppermost nanosheet NS. For example, the upper surface of the lower sheet separation wall SWL may overlap the uppermost nanosheet NS from among the plurality of nanosheets NS in the second horizontal direction (e.g., Y direction).

Referring to FIG. 2H, a fourth material layer CDL4 on (e.g., covering or overlapping) an upper surface (e.g., a top surface) of the lower sheet separation wall SWL and a surface of the third material layer CDL3 may be formed. The fourth material layer CDL4 may conformally cover the upper surface (e.g., the top surface) of the lower sheet separation wall SWL and the surface of the third material layer CDL3 and may not completely (e.g., entirely or fully) fill the plurality of trenches TRE and the separation recess WTR. For example, the fourth material layer CDL4 may be in (e.g., may partially fill) the plurality of trenches TRE and the separation recess WTR. The fourth material layer CDL4 may include (e.g., may be formed of) an insulating material. For example, the fourth material layer CDL4 may include (e.g., may be formed of) silicon carbonate. For example, the fourth material layer CDL4 may be formed by using thermal oxidation, ALD, CVD, PVD, MOALD, and/or MOCVD.

Referring to FIG. 2I, a preliminary upper separation layer SWUP on (e.g., covering or overlapping) the fourth material layer CDL4 and (at least partially) filling the upper portion of the separation recess WTR may be formed. The preliminary upper separation layer SWUP may be in (e.g., may completely (e.g., entirely or fully) fill) the separation recesses WTR and may be in (e.g., may partially fill) the plurality of trenches TRE. For example, the preliminary upper separation layer SWUP may include (e.g., may be formed of) silicon nitride.

Referring to FIGS. 2I and 2J together, an upper sheet separation wall SWU may be formed by removing a portion (e.g., an upper portion) of the preliminary upper separation layer SWUP. The upper sheet separation wall SWU may be in (e.g., may fill) a part of the upper portion of the separation recess WTR. The upper sheet separation wall SWU may partially fill the upper portion of the separation recess WTR. While the upper sheet separation wall SWU is formed, (all portions of) the preliminary upper separation layer SWUP in (filling) the plurality of trenches TRE may be removed. For example, the upper sheet separation wall SWU may not fill a part of the upper portion of the separation recess WTR. An upper surface (e.g., an uppermost surface) of the upper sheet separation wall SWU may be located at a vertical level higher than that of (the upper surface of) the uppermost nanosheet NS from among the plurality of nanosheets NS and lower than that of an upper surface (e.g., a top surface) of the hard mask pattern HMK. For example, the upper surface of the upper sheet separation wall SWU may overlap the hard mask pattern HMK and/or the buffer layer BFL in the second horizontal direction (e.g., Y direction). In the second horizontal direction (e.g., Y direction), a horizontal width of the upper sheet separation wall SWU may be less than a horizontal width of the lower sheet separation wall SWL. For example, in the second horizontal direction (e.g., Y direction), a horizontal width of the upper sheet separation wall SWU may be less than a horizontal width of the lower sheet separation wall SWL by twice a thickness of the fourth material layer CDL4.

The upper sheet separation wall SWU and the lower sheet separation wall SWL may constitute the sheet separation wall SWS. The upper sheet separation wall SWU and the lower sheet separation wall SWL may be spaced apart from each other in the vertical direction (e.g., Z direction) (by the fourth material layer CDL4). A portion of the fourth material layer CDL4 may be located between the upper sheet separation wall SWU and the lower sheet separation wall SWL.

Referring to FIGS. 2J and 2K together, physical properties of a portion of the fourth material layer CDL4 exposed to the outside and a portion of the third material layer CDL3 contacting the portion of the fourth material layer CDL4 may be changed to form a fifth material layer CDL5. The fifth material layer CDL5 may include (e.g., may be formed of) an insulating material.

A remaining (unchanged) portion of the third material layer CDL3 may remain as a first insulating pattern CDL3P, and a remaining (unchanged) portion of the fourth material layer CDL4 may remain as a sheet barrier pattern CDL4P. The first insulating pattern CDL3P may be located between the sheet separation wall SWS and the first material layer CDL1, and the sheet barrier pattern CDL4P may be on (e.g., may cover or overlap) a side surface and a lower surface (e.g., a bottom surface) of the upper sheet separation wall SWU. A portion of the sheet barrier pattern CDL4P may be located between the upper sheet separation wall SWU and the lower sheet separation wall SWL.

Referring to FIGS. 2K and 2L together, the fifth material layer CDL5 and the portion of the first material layer CDL1 contacting the fifth material layer CDL5 may be removed. A (remaining) portion of the first material layer CDL1 may remain as a second insulating pattern CDL1P. For example, a portion of the first material layer CDL1 contacting the first insulating pattern CDL3P may remain as the second insulating pattern CDL1P.

Referring to FIG. 2M, a sixth material layer CDL6 on (e.g., covering or overlapping) exposed surfaces of the base substrate layer BSUB, the plurality of sacrificial layers SL, the plurality of nanosheets NS, the plurality of buffer layers BFL, the plurality of hard mask patterns HMK, the upper sheet separation wall SWU, the first insulating pattern CDL3P, the second insulating pattern CDL1P, and the sheet barrier pattern CDL4P may be formed. The sixth material layer CDL6 may include (e.g., may be formed of) a semiconductor material. For example, the sixth material layer CDL6 may include (e.g., may be formed of) silicon. For example, the sixth material layer CDL6 may be formed by using thermal oxidation, ALD, CVD, PVD, MOALD, and/or MOCVD.

The sixth material layer CDL6 may include a first layer CDL6A and a second layer CDL6B. The first layer CDL6A may be a portion of the sixth material layer CDL6 on (e.g., covering or overlapping) (a surface of) a crystalline material and/or a polycrystalline material, and the second layer CDL6B may be a portion of the sixth material layer CDL6 on (e.g., covering or overlapping) a surface of an amorphous material. The first layer CDL6A and the second layer CDL6B may have different physical properties. For example, the first layer CDL6A may include (e.g., may be formed of) a crystalline material and/or polycrystalline material, and the second layer CDL6B may include (e.g., may be formed of) an amorphous material. In some embodiments, the first layer CDL6A may be a portion of the sixth material layer CDL6 on (e.g., covering or overlapping) a surface of a semiconductor material, and the second layer CDL6B may be a portion of the sixth material layer CDL6 on (e.g., covering or overlapping) a surface of an insulating material. For example, the first layer CDL6A may be on (e.g., may conformally cover or may overlap) exposed surfaces of the base substrate layer BSUB, the plurality of sacrificial layers SL, and the plurality of nanosheets NS, and the second layer CDL6B may be on (e.g., may cover or may overlap) exposed surfaces of the plurality of buffer layers BFL, the plurality of hard mask patterns HMK, the upper sheet separation wall SWU, the first insulating pattern CDL3P, the second insulating pattern CDL1P, and the sheet barrier pattern CDL4P.

Referring to FIG. 2N, a seventh material layer CDL7 on (e.g., covering or overlapping) the sixth material layer CDL6 may be formed. The seventh material layer CDL7 may have a thickness great enough to cover an entire uppermost end of the sixth material layer CDL6. The seventh material layer CDL7 may include (e.g., may be formed of) an insulating material. For example, the seventh material layer CDL7 may include (e.g., may be formed of) silicon oxide, silicon nitride, silicon oxynitride, and/or a combination thereof.

Referring to FIGS. 2N and 2O together, a physical property of a portion of the sixth material layer CDL6 may be changed. For example, a portion of the sixth material layer CDL6 located in the plurality of trenches TRE may be oxidized to form a portion of the seventh material layer CDL7. For example, the seventh material layer CDL7 may expand to include a portion of the sixth material layer CDL6 by changing a physical property of (e.g., oxidizing) the portion of the sixth material layer CDL6 to that of the seventh material layer CDL7. A remaining portion of the sixth material layer CDL6 may remain as a cover pattern CDL6P. The cover pattern CDL6P may be on (e.g., cover or overlap) an upper surface (e.g., a top surface) of the hard mask pattern HMK. The cover pattern CDL6P may be on (the upper surface and the side surface of) the hard mask pattern HMK, (the upper surface of) the upper sheet separation wall SWU, (the upper surface of) the first insulating pattern CDL3P, (the upper surface of) the second insulating pattern CDLIP, and (the upper surface of) the sheet barrier pattern CDL4P.

Referring to FIGS. 2O and 2P together, (an upper surface of) the cover pattern CDL6P may be exposed by removing a part of an upper portion of the seventh material layer CDL7. In some embodiments, an upper surface (e.g., a top surface) of the seventh material layer CDL7 from which the part of the upper portion of the seventh material layer CDL7 is removed and an upper surface (e.g., a top surface) of the cover pattern CDL6P may be located at the same vertical level (may be coplanar with each other).

Referring to FIGS. 2P and 2Q together, a part of the upper portion of the seventh material layer CDL7 may be further removed so that the cover pattern CDL6P may protrude (may be exposed) from an upper surface (e.g., a top surface) of the seventh material layer CDL7 from which the part of the upper portion is further removed.

Referring to FIGS. 2Q and 2R together, a portion of the cover pattern CDL6P may be removed. In some embodiments, a portion of the cover pattern CDL6P on (e.g., covering or overlapping) an upper surface (e.g., a top surface) of the hard mask pattern HMK, and a portion of the cover pattern CDL6P located between (a side surface of) the hard mask pattern HMK and (a side surface of) a portion of the seventh material layer CDL7 located in the separation recess WTR may be removed.

Referring to FIGS. 2R and 2S together, the plurality of hard mask patterns HMK may be removed.

Referring to FIGS. 2S and 2T together, a part of an upper portion of the seventh material layer CDL7 may be removed to form a device isolation film STI that is a remaining portion of the seventh material layer CDL7. For example, the device isolation film STI may include (e.g., may be formed of) silicon oxide, silicon nitride, and/or silicon oxynitride. The device isolation film STI may have a single-layer structure including one type of insulating film or a multi-layer structure including more than one types of insulating films. For example, the device isolation film STI may include two different types of insulating films. For example, the device isolation film STI may include a silicon oxide film and a silicon nitride film. For example, the device isolation film STI may have a three layer-structure (the multi-layer structure) including a silicon oxide film, a silicon nitride film, and a silicon oxide film.

To form the device isolation film STI, while the part of the upper portion of the seventh material layer CDL7 is removed, a portion of the first insulating pattern CDL3P, a portion of the second insulating pattern CDL1P, a portion of the cover pattern CDL6P, and the plurality of buffer layers BFL may be removed together. For example, from among the first insulating pattern CDL3P and the second insulating pattern CDLIP, a portion (an upper portion) of the first insulating pattern CDL3P and a portion (an upper portion) of the second insulating pattern CDL1P located above an upper surface (e.g., a top surface) of the uppermost nanosheet NS from among the plurality of nanosheets NS, and a portion of the cover pattern CDL6P on (e.g., covering or overlapping) (upper surfaces of) the first insulating pattern CDL3P and the second insulating pattern CDLIP may be removed together with the part of the upper portion of the seventh material layer CDL7.

The upper sheet separation wall SWU may be surrounded by the cover pattern CDL6P and the sheet barrier pattern CDLAP. For example, the sheet barrier pattern CDLAP may be on a side surface and a lower surface of the upper sheet separation wall SWU, and the cover pattern CDL6P may be on an upper surface of the upper sheet separation wall SWU.

Referring to FIG. 2U, an eighth material layer CDL8 on (e.g., covering or overlapping) surfaces of the device isolation film STI, the plurality of sacrificial layers SL, the plurality of nanosheets NS, the cover pattern CDL6P, and the sheet barrier pattern CDL4P may be formed. The eighth material layer CDL8 may include (e.g., may be formed of) an insulating material. For example, the eighth material layer CDL8 may include (e.g., may be formed of) silicon oxide. In some embodiments, the eighth material layer CDL8 may be a dummy gate insulating layer. In some embodiments, a portion of the eighth material layer CDL8 on (e.g., covering or overlapping) an upper surface (e.g., a top surface) of the device isolation film STI may be a portion of the device isolation film STI. The eighth material layer CDL8 may be on (e.g., covering or overlapping) the first insulating pattern CDL3P and the second insulating pattern CDL1P.

In some embodiments, an upper surface (e.g., a top surface) of the device isolation film STI may be located at a vertical level (substantially) the same as that of an upper surface (e.g., a top surface) of the fin-type active area FA. For example, the upper surface of the device isolation film STI may be coplanar with the upper surface of the fin-type active area FA. For example, the fin-type active area FA may be a portion of the base substrate layer BSUB defined by the device isolation film STI.

Referring to FIGS. 3A, 3B, and 3C, a dummy gate electrode DPC on (e.g., covering or overlapping) the eighth material layer CDL8 may be formed, and then the dummy gate electrode DPC and the eighth material layer CDL8 may be patterned and separated into a plurality of parts. Next, a gate spacer GSP on (e.g., covering or overlapping) a side surface of each of the patterned dummy gate electrode DPC and the patterned eighth material layer CDL8 may be formed. The dummy gate electrode DPC may include (e.g., may be formed of) polysilicon, and the gate spacer GSP may include (e.g., may be formed of) silicon nitride.

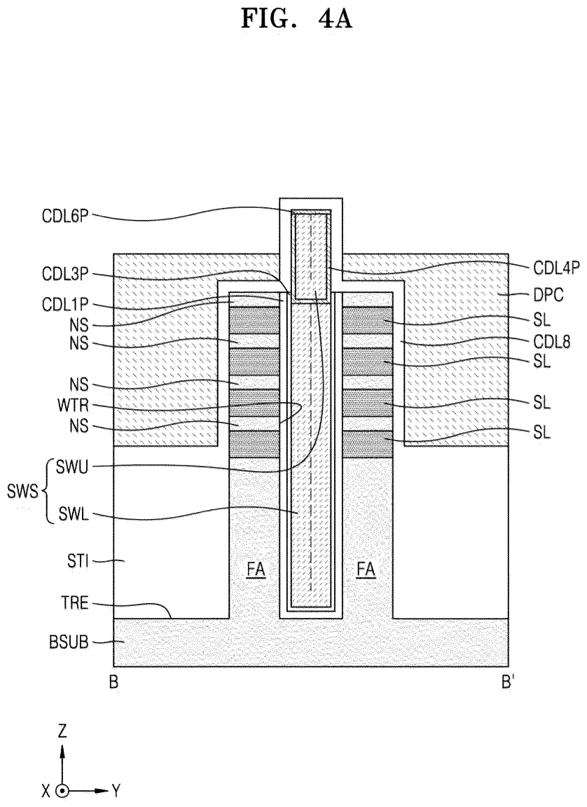

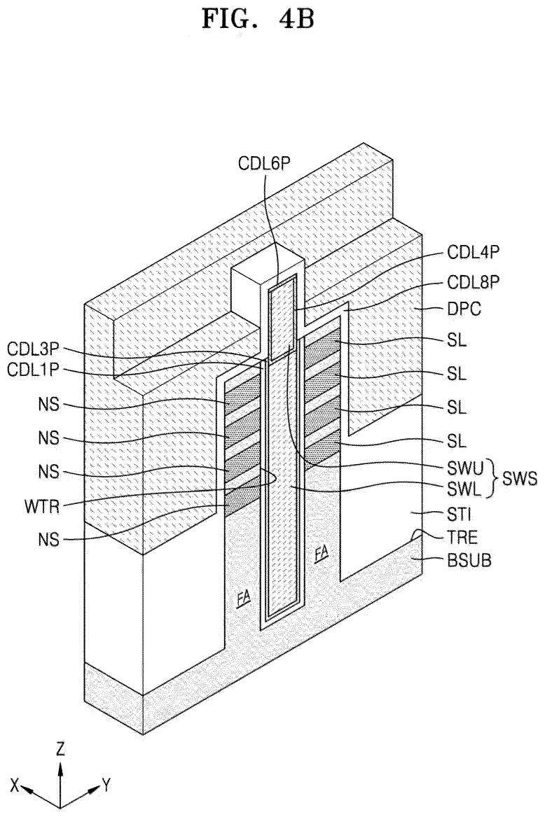

Referring to FIGS. 4A and 4B together, a part of an upper portion of the eighth material layer CDL8 may be exposed by removing a part of an upper portion of the dummy gate electrode DPC. The part of the upper portion of the dummy gate electrode DPC may be removed so that a portion of the eighth material layer CDL8 on (e.g., covering or overlapping) an upper surface (e.g., a top surface) of the uppermost nanosheet NS from among the plurality of nanosheets NS is not exposed.

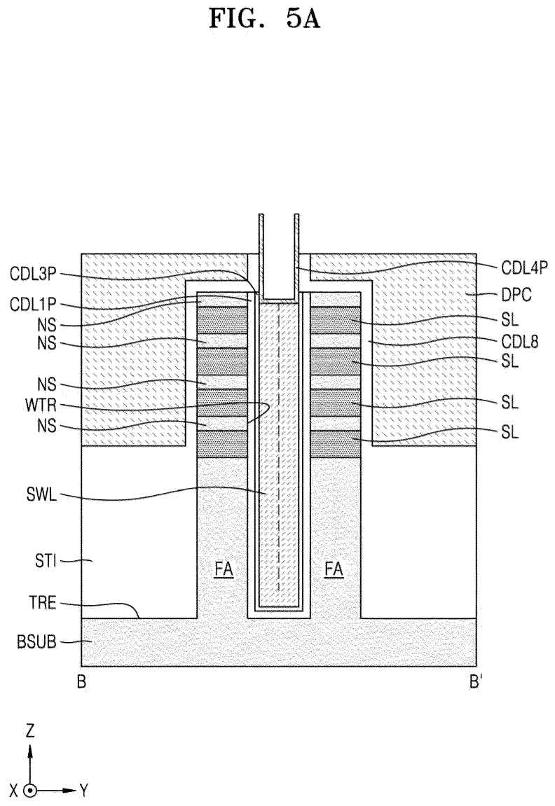

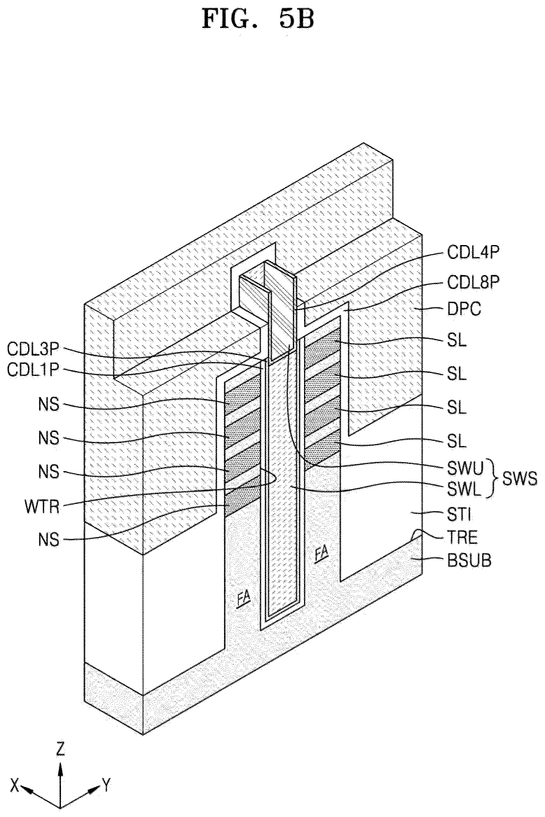

Referring to FIGS. 4A and 4B and 5A and 5B together, a portion of the eighth material layer CDL8 exposed by removing the part of the upper portion of the dummy gate electrode DPC may be removed, and then a portion of the cover pattern CDL6P and a portion of the upper sheet separation wall SWU may be removed.

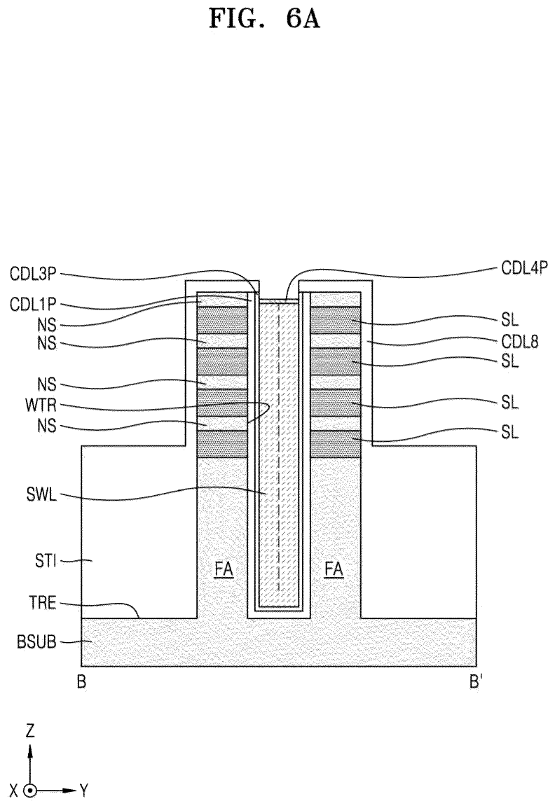

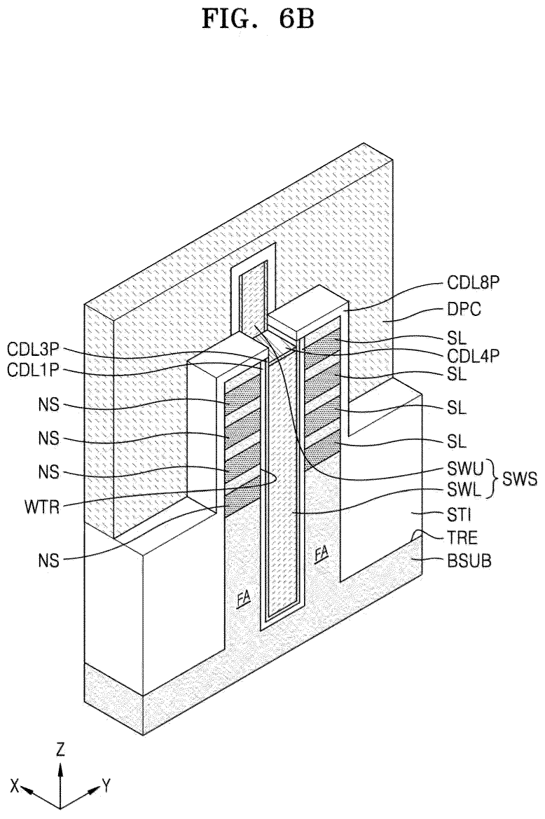

Referring to FIGS. 5A and 5B and 6A and 6B together, a portion of the cover pattern CDL6P and a portion of the upper sheet separation wall SWU may be removed, and then the eighth material layer CDL8 and the device isolation film STI may be exposed by further removing a portion of the dummy gate electrode DPC. Next, a part of an upper portion of the sheet barrier pattern CDL4P may be removed. A portion of the sheet barrier pattern CDL4P on (e.g., covering or overlapping) an upper surface (e.g., a top surface) of the lower sheet separation wall SWL may be maintained (remained) without being removed. For example, only the portion of the sheet barrier pattern CDL4P on the upper surface of the lower sheet separation wall SWL may remain after the removal of the part of the upper portion of the sheet barrier pattern CDL4P. In a cross-sectional view, the removed part of the upper portion of the sheet barrier pattern CDLAP may be a portion of the sheet barrier pattern CDL4P extending in the vertical direction (e.g., Z direction).

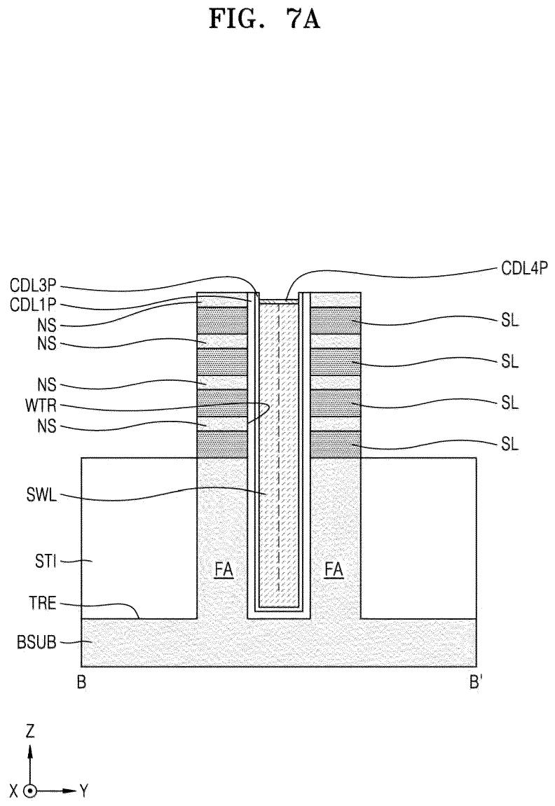

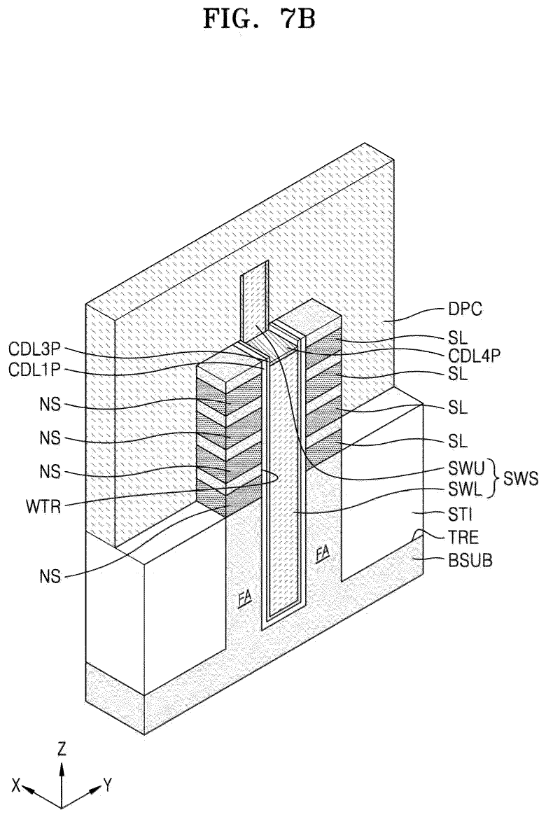

Referring to FIGS. 6A and 6B and 7A and 7B together, a portion of the plurality of sacrificial layers SL and a portion of the plurality of nanosheets NS may be exposed by removing an exposed portion of the eighth material layer CDL8.

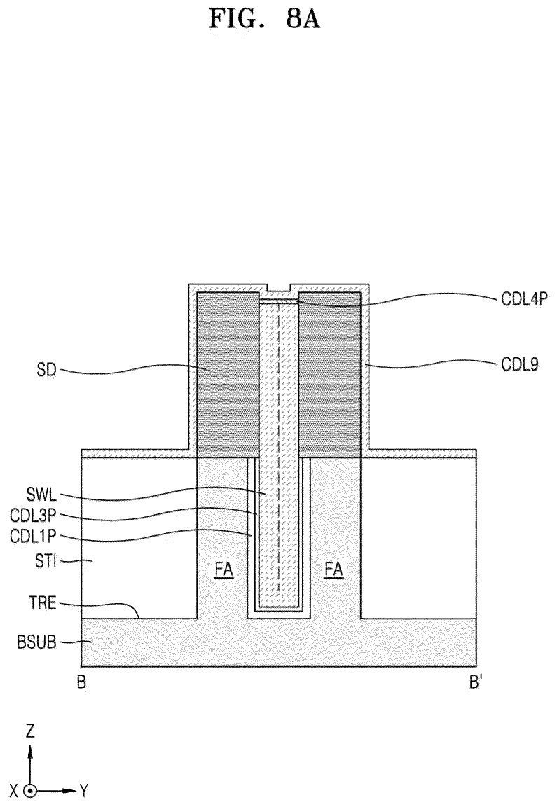

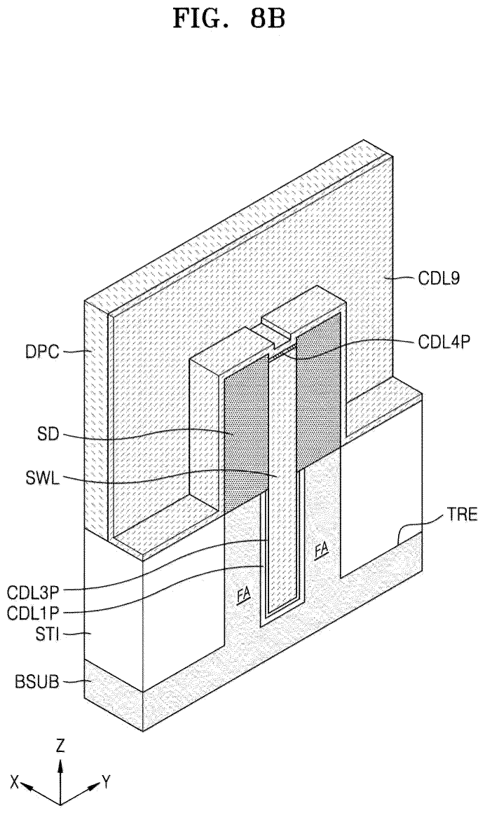

Referring to FIGS. 7A and 7B and 8A and 8B together, a portion of the plurality of sacrificial layers SL and a portion of the plurality of nanosheets NS, which are exposed, and a portion of the second insulating pattern CDLIP and a portion of the first insulating pattern CDL3P adjacent to the portion of the plurality of sacrificial layers SL and the portion of the plurality of nanosheets NS may be removed, and then the plurality of source/drain regions SD may be formed on (from) a remaining portion of the plurality of nanosheets NS and the plurality of fin-type active areas FA. Next, a ninth material layer CDL9 on (conformally covering or overlapping) surfaces of the plurality of source/drain regions SD, the device isolation film STI, the sheet barrier pattern CDL4P, and the dummy gate electrode DPC may be formed. The ninth material layer CDL9 may include (e.g., may be formed of) an insulating material. For example, the ninth material layer CDL9 may include (e.g., may be formed of) silicon nitride.

Each of the plurality of source/drain regions SD may include an embedded SiGe structure including a plurality of epitaxially grown SiGe layers, an epitaxially grown Si layer, and/or an epitaxially grown SiC layer.

In some embodiments, some (a first group) and others (a second group) of the plurality of source/drain regions SD may include impurities of different conductivity types. In some embodiments, (a first group of) a plurality of nanosheets NS contacting some (the first group) of the plurality of source/drain regions SD and (a second group of) a plurality of nanosheets NS contacting others (the second group) of the plurality of source/drain regions SD may include impurities of different conductivity types. For example, an n-type metal oxide semiconductor (NMOS) transistor may be formed in a portion where some (the first group) of the plurality of source/drain regions SD are formed, and a p-type metal oxide semiconductor (PMOS) transistor may be formed in a portion where others (the second group) of the plurality of source/drain regions SD are formed. For example, some (the first group) of the plurality of source/drain regions SD may include n-type impurities, others (the second group) of the plurality of source/drain regions SD may include p-type impurities, (the first group of) a plurality of nanosheets NS contacting the some (the first group) of the plurality of source/drain regions SD may include p-type impurities, and (the second group of) a plurality of nanosheets NS contacting the others (the second group) of the plurality of source/drain regions SD may include n-type impurities.

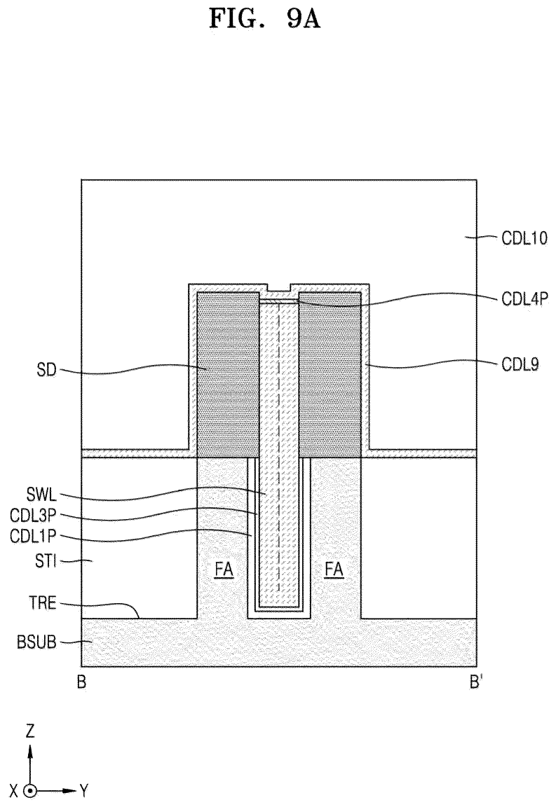

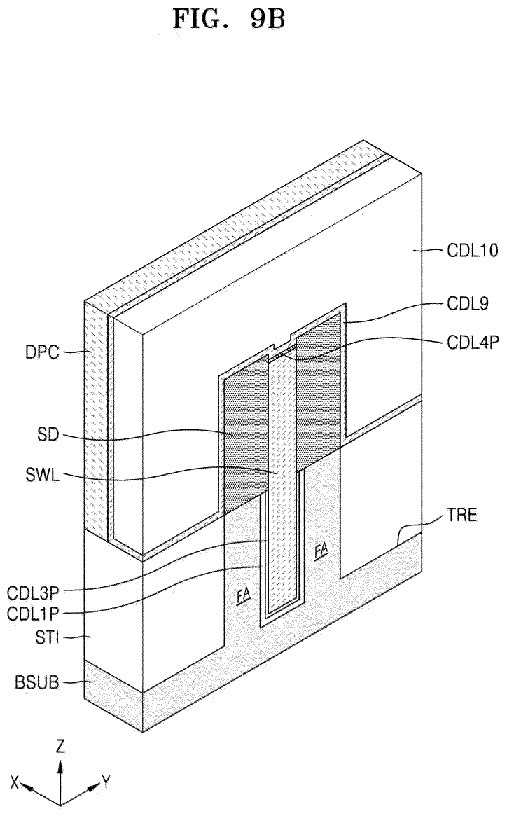

Referring to FIGS. 9A and 9B together, a tenth material layer CDL10 on (e.g., covering or overlapping) the ninth material layer CDL9 may be formed. The tenth material layer CDL10 may be an interlayer insulating layer ILD. For example, the tenth material layer CDL10 may include (e.g., may be formed of) silicon oxide and/or an insulating material having a lower dielectric constant than silicon oxide. In some embodiments, the interlayer insulating layer ILD may include a tetraethyl orthosilicate (TEOS) film and/or an ultra low-K (ULK) film having an ultra low dielectric constant K of (about) 2.2 to (about) 2.4. The ULK film may include a SiOC film and/or a SiCOH film.

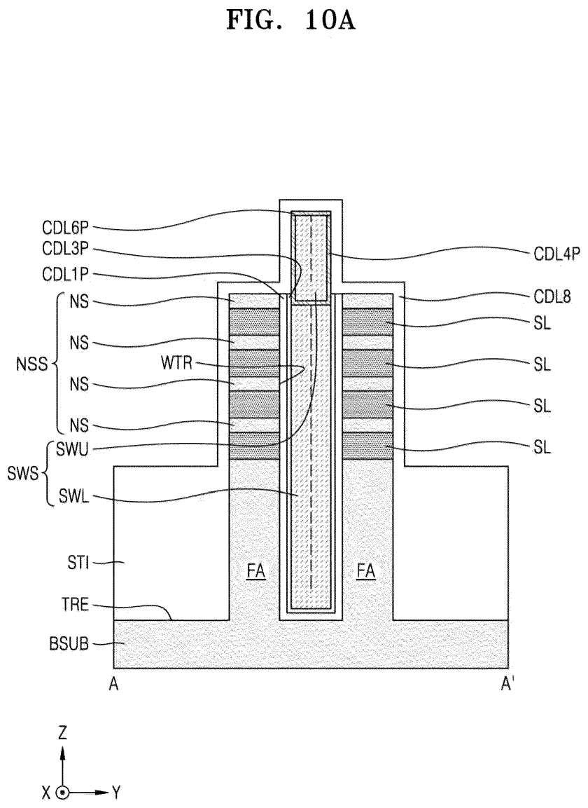

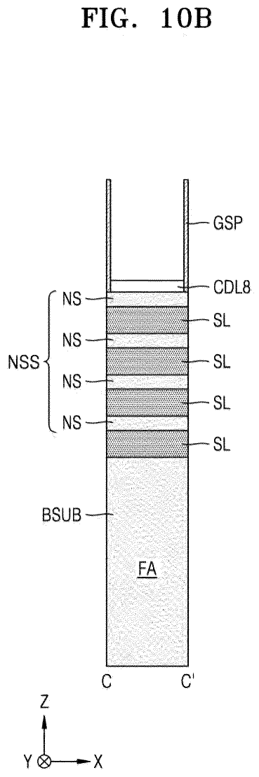

Referring to FIGS. 9A and 9B and 10A and 10B together, after the tenth material layer CDL10 is formed, the dummy gate electrode DPC (e.g., a remained portion of the dummy gate electrode DPC after the processes illustrated in FIGS. 6A and 6B) may be removed. In some embodiments, the dummy gate electrode DPC may be removed by performing wet etching. To perform the wet etching, an etchant including (e.g., formed of), for example, HNO₃, diluted fluoric acid (DHF), NH₄OH, tetramethyl ammonium hydroxide (TMAH), KOH, and/or a combination thereof, may be used.

After the plurality of source/drain regions SD are formed, the plurality of nanosheets NS located on each of the plurality of fin-type active areas FA may be referred to as the nanosheet stacked structure NSS. Each of the plurality of nanosheet stacked structures NSS may include, but is not limited to, four nanosheets NS sequentially located upward to be spaced apart from each other in the vertical direction (e.g., Z direction). For example, each of the plurality of nanosheet stacked structures NSS may include three nanosheets NS or five or more nanosheets NS.

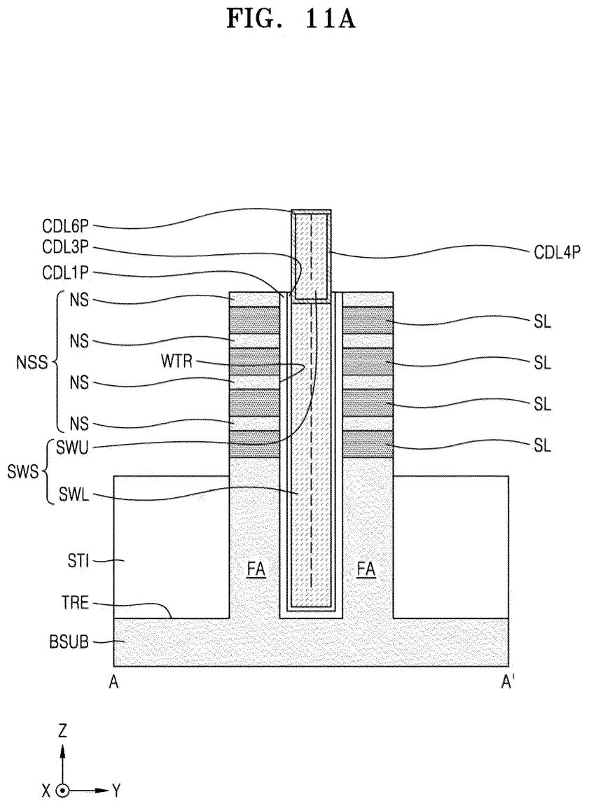

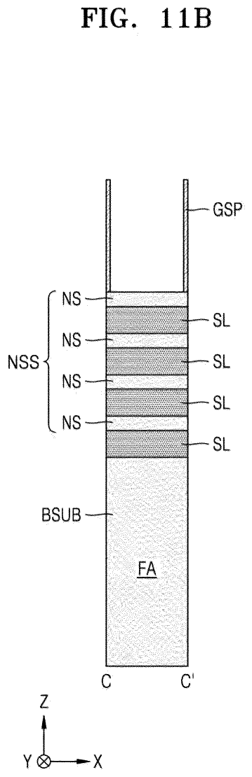

Referring to FIGS. 10A and 10B and 11A and 11B together, a portion of the plurality of sacrificial layers SL and a portion of the plurality of nanosheets NS may be exposed by removing the eighth material layer CDL8 exposed by removing the dummy gate electrode DPC.

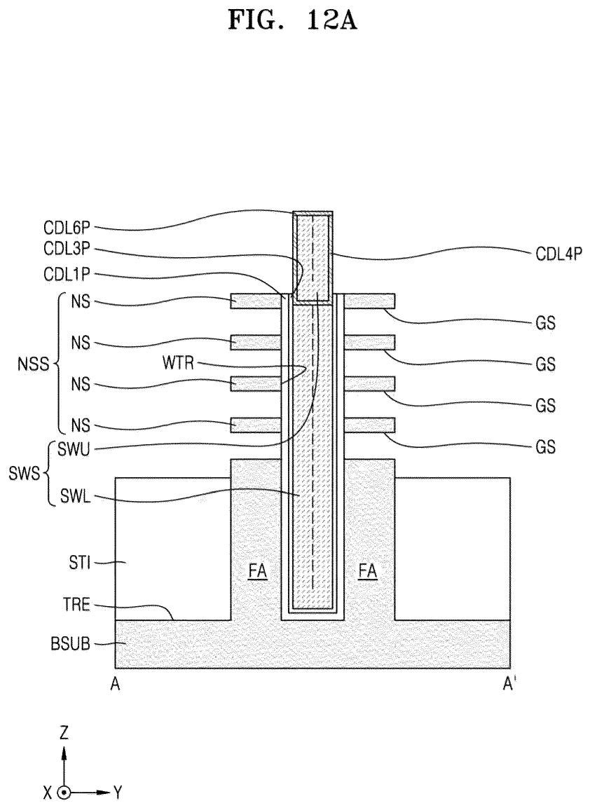

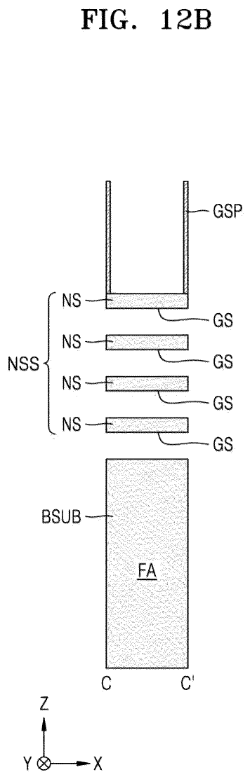

Referring to FIGS. 11A and 11B and 12A and 12B together, by removing the plurality of sacrificial layers SL, a plurality of gate spaces GS may be formed between the fin-type active area FA and a lowermost nanosheet NS from among the plurality of nanosheets NS and between two nanosheets NS adjacent to each other in the vertical direction (e.g., Z direction) from among the plurality of nanosheets NS.

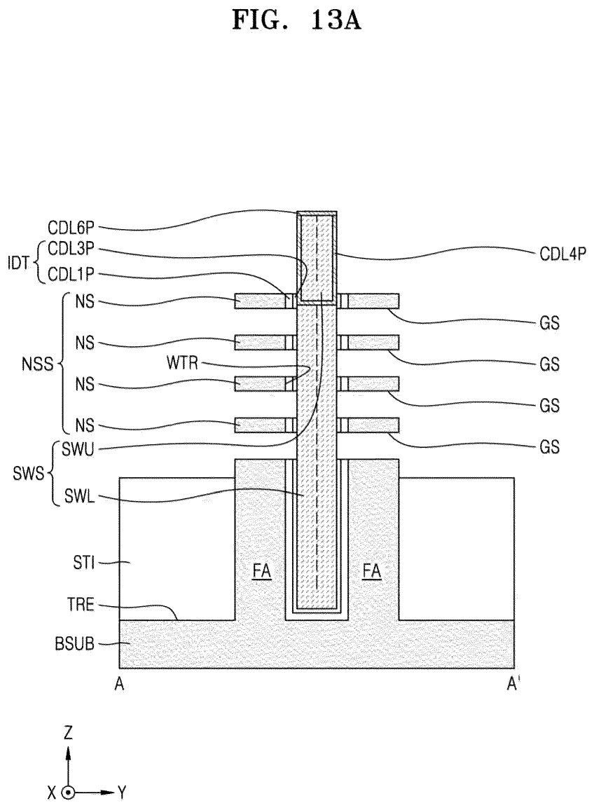

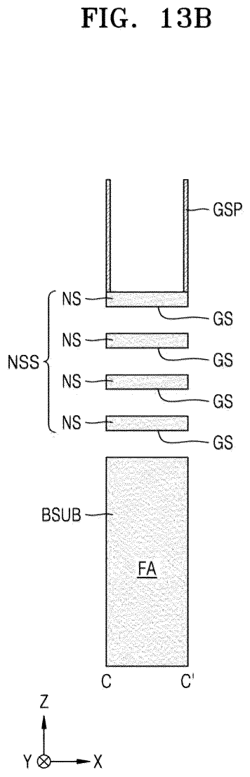

Referring to FIGS. 12A and 12B and 13A and 13B together, after the plurality of sacrificial layers SL are removed, the second insulating pattern CDLIP and the first insulating pattern CDL3P may be separated into a plurality of parts by removing a portion of the second insulating pattern CDLIP and a portion of the first insulating pattern CDL3P located inside (e.g., overlapping in the second horizontal direction (e.g., Y direction) with) each of the plurality of gate spaces GS, and portions of the lower sheet separation wall SWL in (e.g., overlapping in the second horizontal direction (e.g., Y direction) with) the plurality of gate spaces GS may be exposed. For example, a portion of the second insulating pattern CDL1P and a portion of the first insulating pattern CDL3P exposed by the plurality of gate spaces GS may be removed to expose portions of the lower sheet separation wall SWL. Each of the plurality of gate spaces GS may extend from an end of the nanosheet NS opposite to the sheet separation wall SWS to a side wall of the lower sheet separation wall SWL. The first insulating pattern CDL3P and the second insulating pattern CDLIP separated into a plurality of parts may be located between the nanosheet NS and the sheet separation wall SWS (in the second horizontal direction (e.g., Y direction). A stacked structure of the first insulating pattern CDL3P and the second insulating pattern CDL1P located between the nanosheet NS and the sheet separation wall SWS may be (collectively) referred to as an indent spacer IDT. A plurality of indent spacers IDT may be located between the sheet separation wall SWS and the plurality of nanosheets NS.

The lower sheet separation wall SWL, the upper sheet separation wall SWU, the sheet barrier pattern CDL4P, and the plurality of indent spacers IDT may function together as a sheet separation wall structure located between a pair of nanosheet stacked structures NSS adjacent to each other in the second horizontal direction (e.g., Y direction). The sheet separation wall structure may have an indent shape in which the indent spacers IDT spaced apart from each other along the vertical direction (e.g., Z direction) are arranged on each of both sides (e.g., opposite sides) in the second horizontal direction (e.g., Y direction).

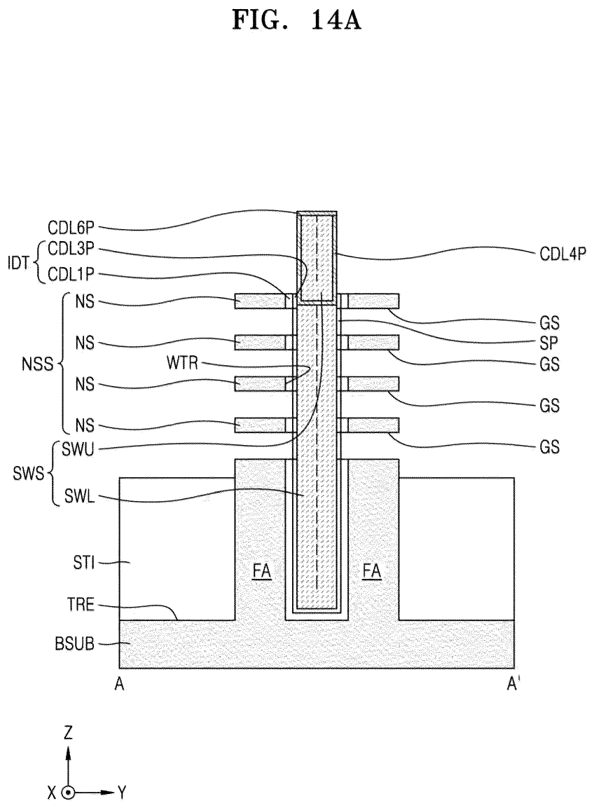

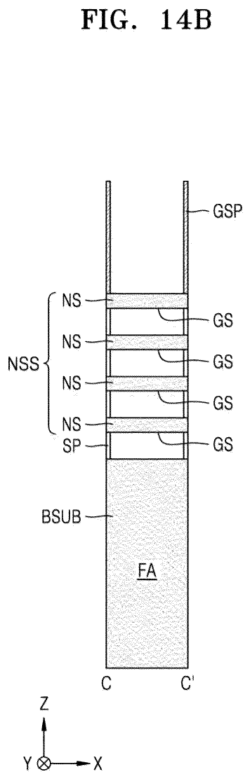

Referring to FIGS. 14A and 14B together, a spacer layer SP may be formed on a surface of the lower sheet separation wall SWL exposed in each of the plurality of gate spaces GS. The spacer layer SP may include (e.g., may be formed of) an insulating material. For example, the spacer layer SP may include (e.g., may be formed of) silicon oxide. The spacer layer SP may also be formed at both ends (e.g., opposite ends) of each of the plurality of gate spaces GS in the first horizontal direction (e.g., X direction). For example, the spacer layer SP may be on (e.g., cover or overlap) the ninth material layer CDL9 (see FIGS. 9A and 9B) located at both ends (e.g., opposite ends) of the plurality of gate spaces GS in the first horizontal direction (e.g., X direction). That is, the spacer layer SP may be on (e.g., may cover or overlap) a surface of the lower sheet separation wall SWL and a surface of the ninth material layer CDL9 in each of the plurality of gate spaces GS.

Although a thickness of the spacer layer SP (in the second horizontal direction (e.g., Y direction)) and a thickness of the second insulating pattern CDLIP (in the second horizontal direction (e.g., Y direction)) on a side surface of the lower sheet separation wall SWL are the same in FIG. 14A, the inventive is not limited thereto. For example, on a side surface of the lower sheet separation wall SWL, a thickness of the spacer layer SP (in the second horizontal direction (e.g., Y direction)) may be less than a thickness of the indent spacer IDT (in the second horizontal direction (e.g., Y direction)).

FIGS. 15A, 15B, 15C, and 15D are vertical cross-sectional views illustrating an integrated circuit device, according to some embodiments. In detail, FIG. 15A is a vertical cross-sectional view taken along line A-A′ of FIG. 1. FIG. 15B is a vertical cross-sectional view taken along line B-B′ of FIG. 1. FIG. 15C is a vertical cross-sectional view taken along line C-C′ of FIG. 1. FIG. 15D is an enlarged view illustrating a portion XVD of FIG. 15A.

Referring to FIGS. 15A, 15B, 15C, and 15D together, the integrated circuit device 1 may be formed by forming a gate insulating layer Gox on (e.g., covering or overlapping) a surface exposed after forming the spacer layer SP and the gate electrode GL on (e.g., covering or overlapping) the gate insulating layer Gox. For example, a plurality of gate insulating layers Gox and a plurality of gate electrodes GL may be formed by using a replacement metal gate (RMG) process.

The gate insulating layer Gox may include a silicon oxide film, a high-k dielectric film, and/or a combination thereof. In some embodiments, the gate insulating layer Gox may have a stacked structure of an interfacial layer and a high-k dielectric film. The interfacial layer may include (e.g., may be formed of) a low dielectric material with a dielectric constant of (about) 9 or less. For example, the interfacial layer may include (e.g., may be formed of) oxide, nitride, and/or oxynitride. The high-k dielectric film may include (e.g., may be formed of) metal oxide and/or metal oxynitride. The high-k dielectric film may include (e.g., may be formed of) a material having a higher dielectric constant than a silicon oxide film. For example, the high-k dielectric film may have a dielectric constant of (about) 10 to (about) 25. The high-k dielectric film may have a thickness of (about) 10 angstroms (Å) to (about) 40 Å, but the inventive concept is not limited thereto. In some embodiments, the interfacial layer may be omitted. For example, the gate insulating layer Gox may include (e.g., may be formed of) HfO₂, Al₂O₃, HfAlO₃, Ta₂O₃, and/or TiO₂.

The gate electrode GL may include a metal-containing layer for adjusting a work function and a metal-containing layer for gap-filling, which fills an upper space of the metal-containing layer for adjusting a work function. The metal-containing layer for adjusting a work function may include, for example, Ti, W, Ru, Nb, Mo, Hf, Ni, Co, Pt, Yb, Tb, Dy, Er, and/or Pd. In some embodiments, the gate electrode GL may have a structure in which a metal nitride layer, a metal layer, a conductive capping layer, and a gap-fill metal film are sequentially stacked. The metal nitride layer and the metal layer may include, for example, Ti, Ta, W, Ru, Nb, Mo, and/or Hf. The gap-fill metal film may include, for example, a W film and/or an Al film. In some embodiments, the gate electrode GL may have, but is not limited to, a stacked structure of TiAlC/TiN/W, a stacked structure of TiN/TaN/TiAlC/TiN/W, or a stacked structure of TiN/TaN/TiN/TiAlC/TiN/W.

Referring to FIGS. 1, 15A, 15B, 15C, and 15D together, the integrated circuit device 1 may include the base substrate layer BSUB including the plurality of fin-type active areas FA protruding in the vertical direction (e.g., Z direction), the plurality of nanosheet stacked structures NSS each including the plurality of nanosheets NS located on the plurality of fin-type active areas FA, the sheet separation wall SWS located on the base substrate layer BSUB and extending along the first horizontal direction (e.g., X direction), and the plurality of gate electrodes GL located on the plurality of nanosheet stacked structures NSS and extending along the second horizontal direction (e.g., Y direction) to intersect the plurality of fin-type active areas FA. In some embodiments, the integrated circuit device 1 may further include at least one gate cut structure PCT extending along the first horizontal direction (e.g., X direction) and cutting across at least some of the plurality of gate electrodes GL. The gate electrodes GL divided into two by the gate cut structure PCT may be spaced apart from each other in the second horizontal direction (e.g., Y direction) with the gate cut structure PCT therebetween.

The plurality of nanosheet stacked structures NSS may be arranged in rows and columns along (in) the first horizontal direction (e.g., X direction) and the second horizontal direction (e.g., Y direction). The plurality of nanosheet stacked structures NSS may be adjacent to the plurality of sheet separation walls SWS and may be arranged in columns along (in) the first horizontal direction (e.g., X direction). A pair of (adjacent) nanosheet stacked structures NSS corresponding to each other from among the plurality of nanosheet stacked structures NSS and a pair of (adjacent) source/drain regions SD corresponding to each other from among the plurality of source/drain regions SD may be spaced apart from each other in the second horizontal direction (e.g., Y direction) with (at least a portion of) the sheet separation wall SWS therebetween. A pair of (adjacent) source/drain regions SD may be spaced apart from each other in the second horizontal direction (e.g., Y direction) with (at least a portion of) the sheet separation wall SWS therebetween and connected to a pair of (adjacent) nanosheet stacked structures NSS spaced apart from each other in the second horizontal direction (e.g., Y direction) with (at least a portion of) the sheet separation wall SWS therebetween.

Each of the plurality of nanosheets NS included in each of the plurality of nanosheet stacked structures NSS may extend parallel to an upper surface (e.g., a top surface) of the fin-type active area FA (in the second horizontal direction (e.g., in Y direction)). The plurality of nanosheets NS may be located on the fin-type active area FA and may be spaced apart from each other along the vertical direction (e.g., Z direction). One end of the plurality of nanosheets NS included in the plurality of nanosheet stacked structures NSS (in the second horizontal direction (e.g., Y direction) may face the plurality of sheet separation walls SWS.

The plurality of gate electrodes GL may be located on an uppermost nanosheet NS from among the plurality of nanosheets NS and between the plurality of nanosheets NS. A main gate portion MG of the plurality of gate electrodes GL located on the uppermost nanosheet NS and a sub-gate portion SG located between the plurality of nanosheets NS may be connected to each other. The spacer layer SP may be located between the sub-gate portion SG and the sheet separation wall SWS.

The plurality of gate insulating layers Gox may be located between the plurality of gate electrodes GL and the plurality of nanosheet stacked structures NSS including the plurality of nanosheets NS and between the plurality of gate electrodes GL and the plurality of fin-type active areas FA. Each of the plurality of source/drain regions SD may be connected to the plurality of nanosheets NS included in each of the plurality of nanosheet stacked structures NSS. Each of the plurality of source/drain regions SD may be connected to the other end of the plurality of nanosheets NS included in each of the plurality of nanosheet stacked structures NSS.

The plurality of nanosheet stacked structures NSS including the plurality of nanosheets NS, the plurality of gate electrodes GL, and the plurality of source/drain regions SD may constitute a plurality of multi-gate metal-oxide-semiconductor field-effect transistors (MOSFETs).

The device isolation film STI may be located in the plurality of trenches TRE. The device isolation film STI may define the plurality of fin-type active areas FA. The ninth material layer CDL9 and the tenth material layer CDL10 may be on (e.g., cover or overlap) the device isolation film STI and the plurality of source/drain regions SD.

A pair of nanosheet stacked structures NSS adjacent to each other in the second horizontal direction (e.g., Y direction) may be spaced apart from the sheet separation wall SWS (by the indent spacer IDT). In some embodiments, the indent spacer IDT may be located between the sheet separation wall SWS and one end of each of the plurality of nanosheets NS included in each of the pair of nanosheet stacked structures NSS adjacent to each other in the second horizontal direction e.g., (Y direction) with the sheet separation wall SWS therebetween. The indent spacer IDT may have a stacked structure (stacked in the second horizontal direction (e.g., Y direction)) of the first insulating pattern CDL3P contacting the sheet separation wall SWS and the second insulating pattern CDLIP contacting (one end of) each of the plurality of nanosheets NS.

Each of the plurality of sheet separation walls SWS may include the lower sheet separation wall SWL and the upper sheet separation wall SWU located on the lower sheet separation wall SWL. A portion of the sheet separation wall SWS located between the pair of nanosheet stacked structures NSS adjacent to each other along (in) the second horizontal direction (e.g., Y direction) may include a portion of the lower sheet separation wall SWL and a portion of the upper sheet separation wall SWU. A portion of the sheet separation wall SWS located between the source/drain regions SD adjacent to each other along (in) the second horizontal direction (e.g., Y direction) may include a portion of the lower sheet separation wall SWL but may not include a portion of the upper sheet separation wall SWU.

The sheet barrier pattern CDL4P may be located between the lower sheet separation wall SWL and the upper sheet separation wall SWU. The sheet barrier pattern CDL4P may be on (e.g., may cover or overlap) a lower surface (e.g., a bottom surface) and both side surfaces (e.g., opposite side surfaces) in the second horizontal direction (e.g., Y direction) of the upper sheet separation wall SWU located between the pair of nanosheet stacked structures NSS adjacent to each other along (in) the second horizontal direction (e.g., Y direction), and may be on (e.g., may cover or overlap) an upper surface (e.g., a top surface) of (at least) a portion of the lower sheet separation wall SWL located between the source/drain regions SD adjacent to each other in the second horizontal direction (e.g., Y direction). The cover pattern CDL6P may be on (e.g., may cover or overlap) an upper surface (e.g., a top surface) of the upper sheet separation wall SWU.

The plurality of lower sheet separation walls SWL may be spaced apart each other along (in) the second horizontal direction (e.g., Y direction) and may each extend in the first horizontal direction (e.g., X direction). The plurality of upper sheet separation walls SWU may be arranged in a matrix to be spaced apart from each other along (in) the first horizontal direction (e.g., X direction) and the second horizontal direction (e.g., Y direction) in a plan view.

The separation recess WTR may be located between one pair of fin-type active areas FA and one pair of nanosheet stacked structures NSS adjacent to each other along (in) the second horizontal direction (e.g., Y direction). A recess width NSD of the separation recess WTR in the second horizontal direction (e.g., Y direction) may be greater than a lower width LWW of the lower sheet separation wall SWL in the second horizontal direction (e.g., Y direction). The recess width NSD may be (about) 35 nanometers (nm) or less. The recess width NSD may be a distance between the pair of fin-type active areas FA adjacent to each other along (in) the second horizontal direction (e.g., Y direction). A height of the fin-type active area FA, for example, a trench depth TRD, which is a vertical distance from an upper surface (e.g., a top surface) of the fin-type active area FA to a lower surface (e.g., a bottom surface) of the device isolation film STI, may be (about) 0.5 nm to (about) 100 nm.

The sheet separation wall SWS may extend upward from the inside of the separation recess WTR to a position above an uppermost end of the pair of (adjacent) nanosheet stacked structures NSS. A lower portion of the lower sheet separation wall SWL may be located between the pair of fin-type active areas FA adjacent to each other along (in) the second horizontal direction (e.g., Y direction), and an upper portion of the lower sheet separation wall SWL may be located between the pair of nanosheet stacked structures NSS adjacent to each other along (in) the second horizontal direction (e.g., Y direction).

A vertical level LWU of an uppermost end of the lower sheet separation wall SWL may be equal to (coplanar with) or higher than a vertical level of a lower surface (e.g., a bottom surface) of the uppermost nanosheet NS from among the plurality of nanosheets NS included in the nanosheet stacked structure NSS. The vertical level LWU of the uppermost end of the lower sheet separation wall SWL may be lower than a vertical level NSU of an upper surface (e.g., a top surface) of the uppermost nanosheet NS by a first depth UWD. For example, the first depth UWD may be (about) 1 nm to (about) 30 nm. In other embodiments, the vertical level LWU of the uppermost end of the lower sheet separation wall SWL may be equal to (coplanar with) or higher than the vertical level NSU of the upper surface (e.g., the top surface) of the uppermost nanosheet NS. For example, the vertical level LWU of the uppermost end of the lower sheet separation wall SWL may be equal to or (about) 5 nm higher than the vertical level NSU of the upper surface (e.g., the top surface) of the uppermost nanosheet NS.

An uppermost end of the upper sheet separation wall SWU may protrude from the upper surface (e.g., the top surface) of the uppermost nanosheet NS in the vertical direction (e.g., Z direction) by an upper protrusion height UWH. The upper protrusion height UWH may be (about) 1 nm to (about) 25 nm. The uppermost end of the upper sheet separation wall SWU and an uppermost end of the sheet barrier pattern CDL4P may be located at the same vertical level (may be coplanar with each other in the vertical direction (e.g., Z direction)).

The lower sheet separation wall SWL may have the lower width LWW (in the second horizontal direction (e.g., Y direction), and the upper sheet separation wall SWU may have an upper width UWW (in the second horizontal direction (e.g., Y direction). In some embodiments, the lower width LWW may be greater than the upper width UWW. For example, the lower width LWW may be greater than the upper width UWW by a thickness of the sheet barrier pattern CDL4P. The lower width LWW may be (about) 30 nm or less.

The vertical level LWU of the uppermost end (the upper surface) of the lower sheet separation wall SWL may be lower than a vertical level SDU of an uppermost end (the upper surface) of the source/drain region SD by a second depth LWD. For example, the second depth LWD may be (about) 1 nm to (about) 10 nm. In other embodiments, the vertical level LWU of the uppermost end (the upper surface) of the lower sheet separation wall SWL may be equal to or higher than the vertical level SDU of the uppermost end (the upper surface) of the source/drain region SD. For example, the vertical level LWU of the uppermost end (the upper surface) of the lower sheet separation wall SWL may be equal to or (about) 30 nm higher than the vertical level SDU of the uppermost end (the upper surface) of the source/drain region SD.

From a side surface of the sheet separation wall SWS, the spacer layer SP may have a first thickness SPT (in the second horizontal direction (e.g., Y direction), and the indent spacer IDT may have a second thickness WND (in the second horizontal direction (e.g., Y direction). The second thickness WND may be greater than the first thickness SPT. For example, the second thickness WND may be (about) 10 nm or less, and the first thickness SPT may be (about) 0.5 nm to (about) 5 nm.

In the separation recess WTR, the lower sheet separation wall SWL of the sheet separation wall SWS and the fin-type active area FA may be spaced apart from each other by a vertical separation distance LWL in the vertical direction (e.g., Z direction) and may be spaced apart from each other by a horizontal separation distance LWS in the second horizontal direction (e.g., Y direction). For example, each of the vertical separation distance LWL and the horizontal separation distance LWS may be (about) 10 nm or less. In some embodiments, each of the vertical separation distance LWL and the horizontal separation distance LWS may be (substantially) the same as the second thickness WND. In the separation recess WTR, a stacked structure of the first insulating pattern CDL3P and the second insulating pattern CDLIP may be located between the lower sheet separation wall SWL of the sheet separation wall SWS and the fin-type active area FA.

A portion of the gate electrode GL filling the gate space GS and facing the sheet separation wall SWS, that is, one end of the sub-gate portion SG, may be closer to the sheet separation wall SWS by an adjacent distance GND in the second horizontal direction (e.g., Y direction) than one end of the nanosheet NS facing the sheet separation wall SWS. The adjacent distance GND may be (about) 7 nm or less. That is, one end of the sub-gate portion SG facing the sheet separation wall SWS may protrude toward the sheet separation wall SWS by the adjacent distance GND in the second horizontal direction (e.g., Y direction) than one end of the nanosheet NS.

In the integrated circuit device 1 according to the inventive concept, because a portion of the gate electrode GL filling the gate space GS and facing the sheet separation wall SWS, that is, one end of the sub-gate portion SG, is closer to the sheet separation wall SWS by the adjacent distance GND in the second horizontal direction e.g., (Y direction) than one end of the nanosheet NS facing the sheet separation wall SWS, an effective channel width may increase. Also, in the integrated circuit device 1 according to the inventive concept, because the sheet separation wall SWS and the nanosheet NS functioning as a channel region are spaced apart from each other due to the indent spacer IDT, leakage current due to a fixed charge may be reduced (e.g., prevented). Accordingly, operational characteristics of the integrated circuit device 1 including a transistor including a multi-gate MOSFET may be improved.

In the integrated circuit device 1 according to the inventive concept, because the sheet separation wall SWS includes the lower sheet separation wall SWL and the upper sheet separation wall SWU formed through a separate process, seams may be prevented from occurring in the sheet separation wall SWS and contamination and/or damage to the plurality of nanosheets NS may be prevented.

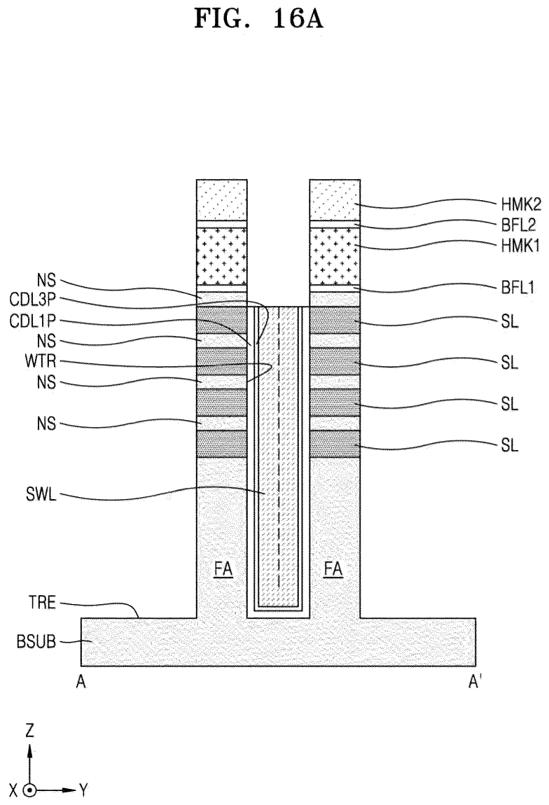

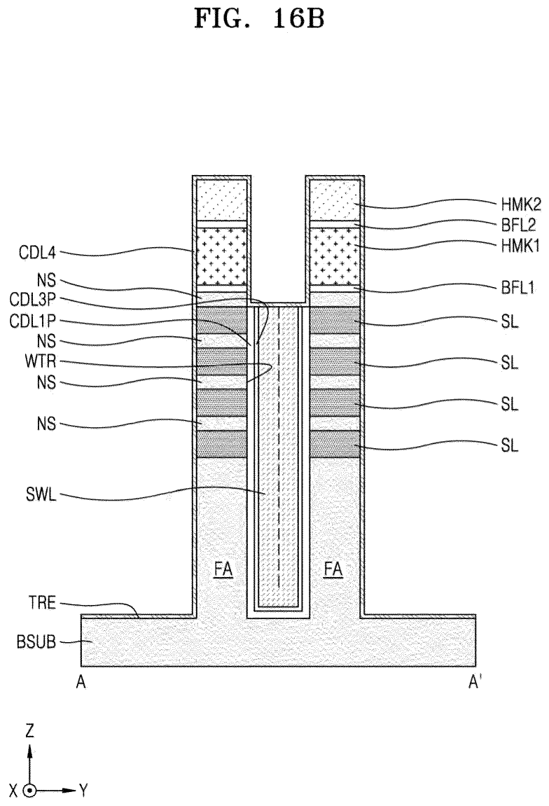

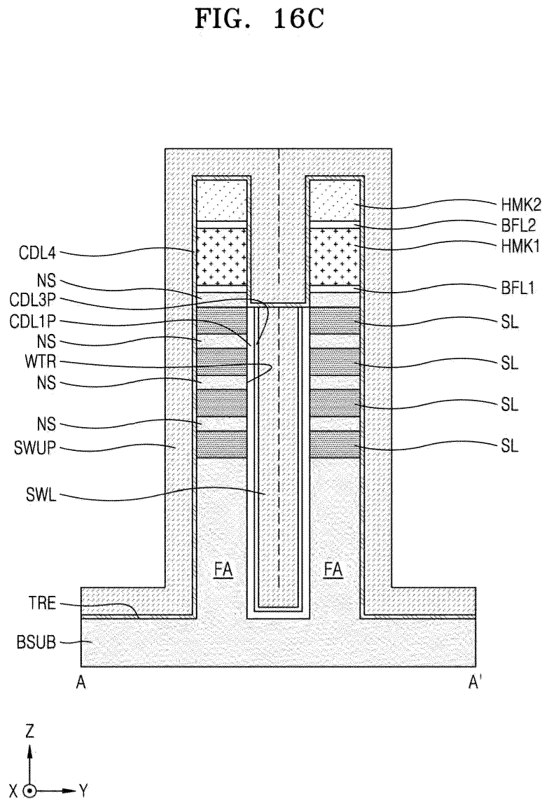

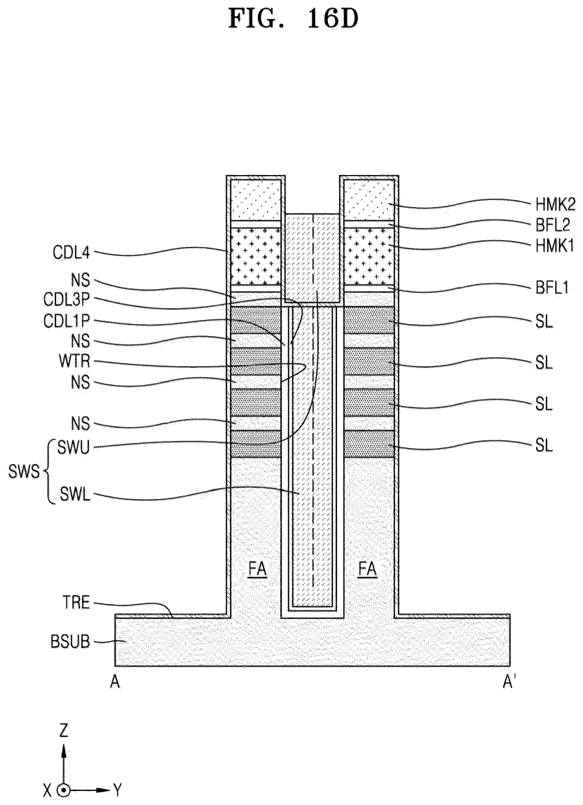

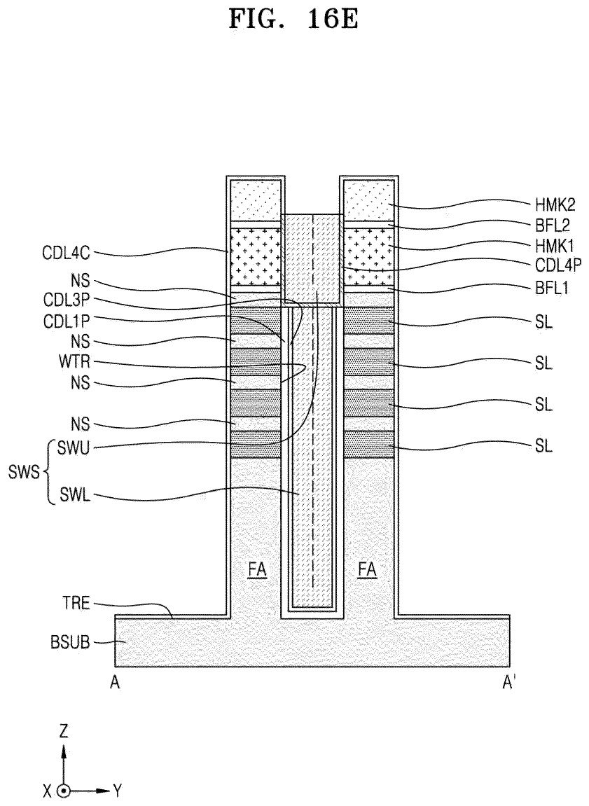

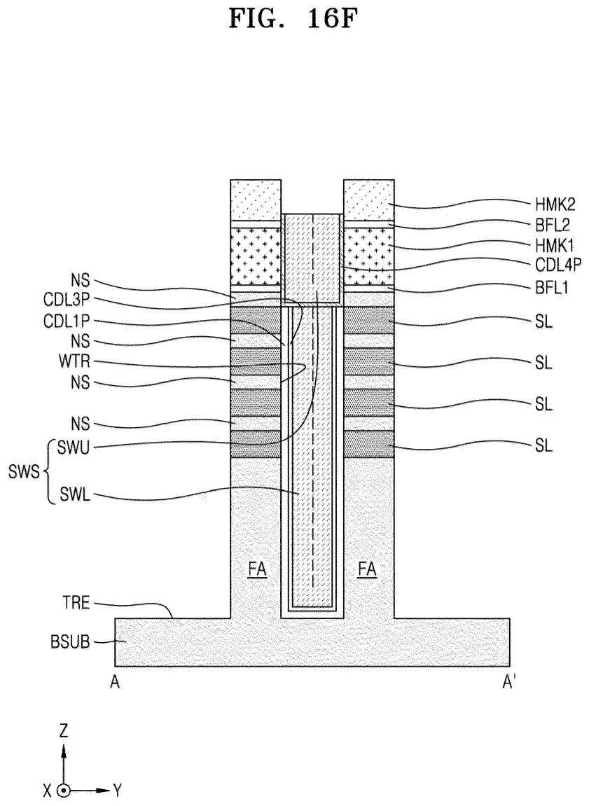

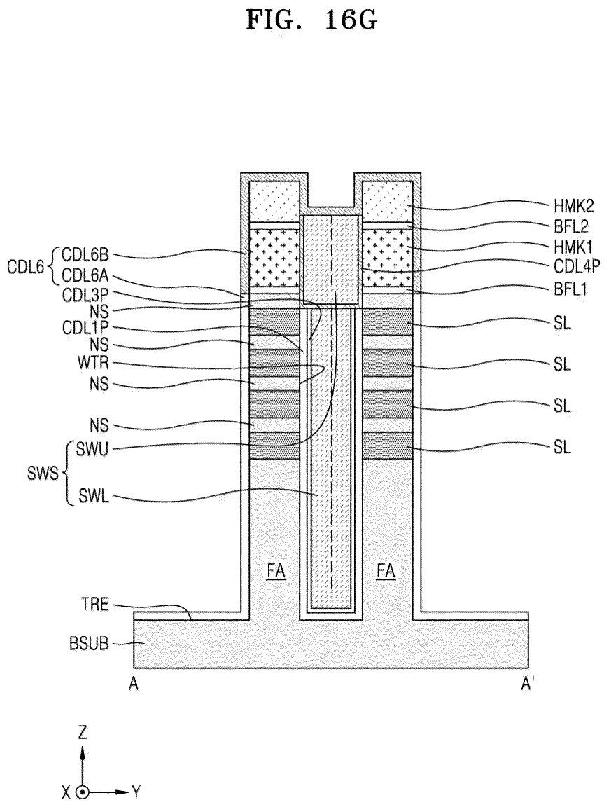

FIGS. 16A, 16B, 16C, 16D, 16E, 16F, and 16G are vertical cross-sectional views for describing a method of manufacturing an integrated circuit device, according to embodiments. In detail, FIGS. 16A, 16B, 16C, 16D, 16E, 16F, and 16G are vertical cross-sectional views taken along line A-A′ of FIG. 1.

Referring to FIGS. 2G and 16A together, a portion of the third material layer CDL3 and a portion of the first material layer CDL1 may be removed. A remaining portion of the third material layer CDL3 may remain as the first insulating pattern CDL3P, and a remaining portion of the first material layer CDL1 may remain as the second insulating pattern CDLIP. For example, in the separation recess WTR, portions of the third material layer CDL3 and the first material layer CDL1 located between the lower sheet separation wall SWL and a stacked structure of the plurality of sacrificial layers SL and the plurality of nanosheets NS may remain as the first insulating pattern CDL3P and the second insulating pattern CDLIP, respectively (without being removed).

In some embodiments, instead of a stacked structure of the buffer layer BFL and the hard mask pattern HMK of FIG. 2G, a stacked structure of a first buffer layer BFL1, a first hard mask pattern HMK1, a second buffer layer BFL2, and a second hard mask pattern HMK2 may be formed on a stacked structure of the plurality of sacrificial layers SL and the plurality of nanosheets NS. The first buffer layer BFL1 and the second buffer layer BFL2 may include (e.g., may be formed of) oxide. In some embodiments, the first buffer layer BFL1 and the second buffer layer BFL2 may include (e.g., may be formed of) the same material. The first hard mask pattern HMK1 and the second hard mask pattern HMK2 may include (e.g., may be formed of) the same material, but the inventive concept is not limited thereto. For example, one of the first hard mask pattern HMK1 and the second hard mask pattern HMK2 may include (e.g., may be formed of) nitride, and the other may include (e.g., may be formed of) an insulating material including carbon.

Referring to FIG. 16B, after the first insulating pattern CDL3P and the second insulating pattern CDLIP are formed, the fourth material layer CDL4 on (e.g., covering or overlapping) an exposed surface may be formed. The fourth material layer CDL4 may include (e.g., may be formed of) an insulating material. For example, the fourth material layer CDL4 may include (e.g., may be formed of) silicon carbonate.

Referring to FIG. 16C, the preliminary upper separation layer SWUP on (e.g., covering or overlapping) the fourth material layer CDL4 and in (at least partially filling) an upper portion of the separation recess WTR may be formed. The preliminary upper separation layer SWUP may completely fill the separation recess WTR but may only partially fill the plurality of trenches TRE. For example, the preliminary upper separation layer SWUP may include (e.g., may be formed of) silicon nitride.

Referring to FIGS. 16C and 16D together, the upper sheet separation wall SWU may be formed by removing a portion of the preliminary upper separation layer SWUP. The upper sheet separation wall SWU may fill a part of the upper portion of the separation recess WTR. The upper sheet separation wall SWU and the lower sheet separation wall SWL may constitute the sheet separation wall SWS. The upper sheet separation wall SWU and the lower sheet separation wall SWL may be spaced apart from each other in the vertical direction (e.g., Z direction) (by the fourth material layer CDL4). A portion of the fourth material layer CDL4 may be located between the upper sheet separation wall SWU and the lower sheet separation wall SWL.

Referring to FIGS. 16D and 16E together, a physical property of a portion of the fourth material layer CDL4 exposed to the outside may be changed to form a change material layer CDL4C. A remaining (unchanged) portion of the fourth material layer CDL4 may remain as the sheet barrier pattern CDL4P. The change material layer CDL4C may have a lower carbon atom content than the sheet barrier pattern CDL4P.

Referring to FIGS. 16E and 16F together, the change material layer CDL4C may be removed. The sheet barrier pattern CDL4P may be remained (maintained) without being removed.

Referring to FIGS. 16E, 16F, and 16G together, the sixth material layer CDL6 on (e.g., conformally covering or overlapping) a surface exposed after removing the change material layer CDL4C may be formed. The sixth material layer CDL6 may include (e.g., may be formed of) a semiconductor material. The sixth material layer CDL6 may include the first layer CDL6A and the second layer CDL6B. The first layer CDL6A and the second layer CDL6B may have different physical properties.

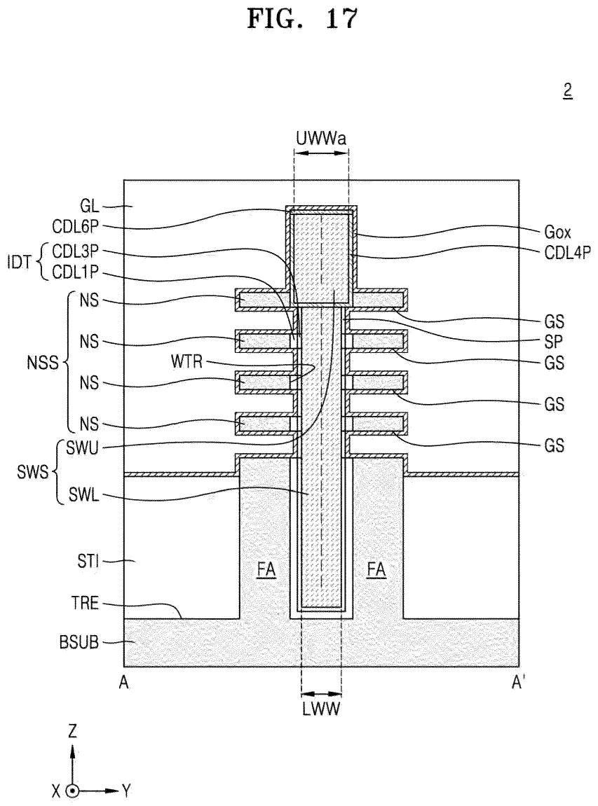

FIG. 17 is a vertical cross-sectional view illustrating an integrated circuit device, according to some embodiments. In detail, FIG. 17 is a vertical cross-sectional view taken along line A-A′ of FIG. 1.

Referring to FIG. 17, after the sixth material layer CDL6 of FIG. 16G is formed, an integrated circuit device 2 may be formed with reference to FIGS. 2N, 2O, 2P, 2Q, 2R, 2S, 2T, 2U, 3A, 3B, 3C, 4A, 4B, 5A, 5B, 6A, 6B, 7A, 7B, 8A, 8B, 9A, 9B, 10A, 10B, 11A, 11B, 12A, 12B, 13A, 13B, 14A, and 14B. The lower sheet separation wall SWL of the sheet separation wall SWS included in the integrated circuit device 2 may have the lower width LWW (in the second horizontal direction (e.g., Y direction)), and the upper sheet separation wall SWU of the sheet separation wall SWS may have an upper width UWWa (in the second horizontal direction (e.g., Y direction)). In some embodiments, the upper width UWWa may be greater than the lower width LWW. For example, the upper width UWWa may be greater than the lower width LWW by (about) 9 nm or less.

In some embodiments, the indent spacer IDT may not be located between the sheet separation wall SWS and the uppermost nanosheet NS from among the plurality of nanosheets NS but may be located between the sheet separation wall SWS and the remaining nanosheets NS (lower than the uppermost nanosheet NS from among the plurality of nanosheets NS).

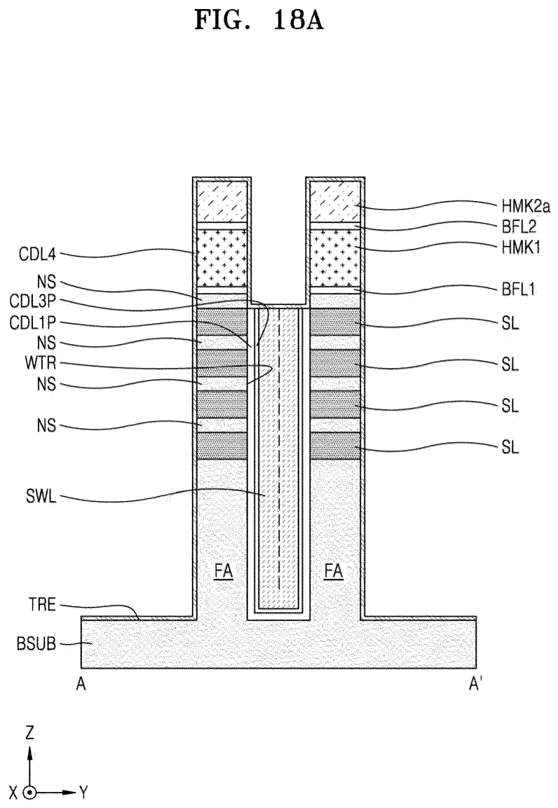

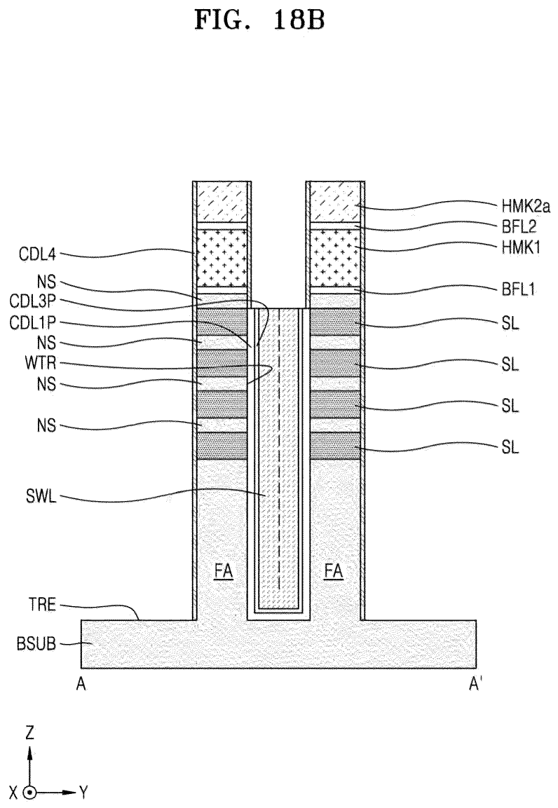

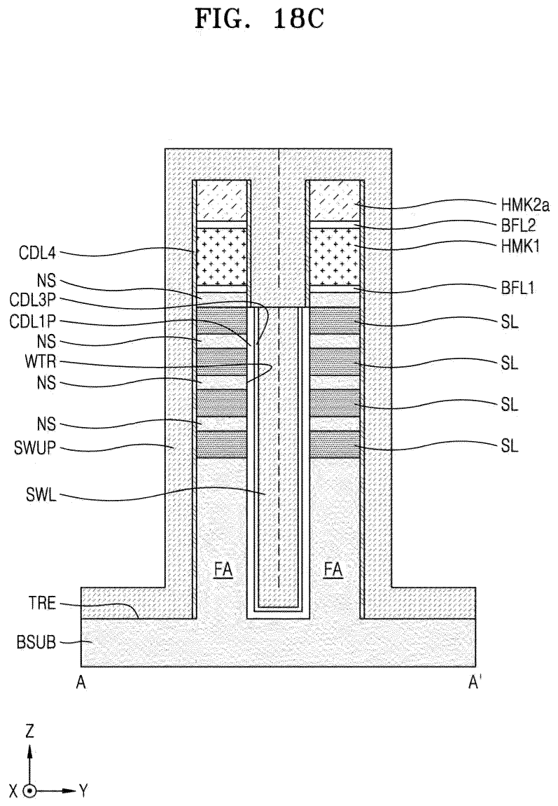

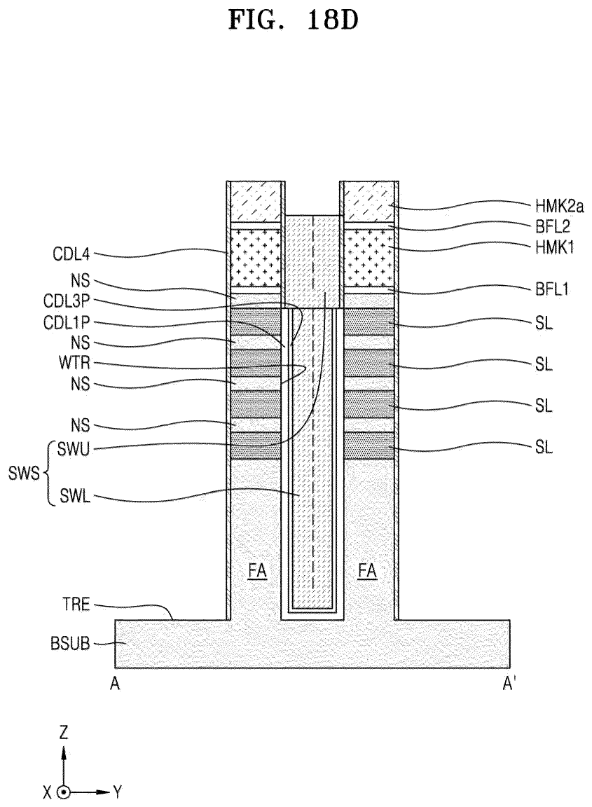

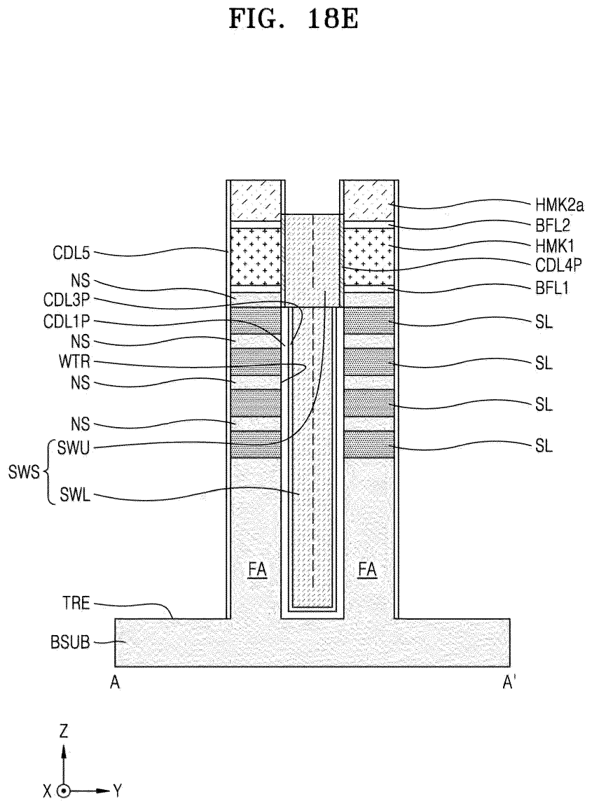

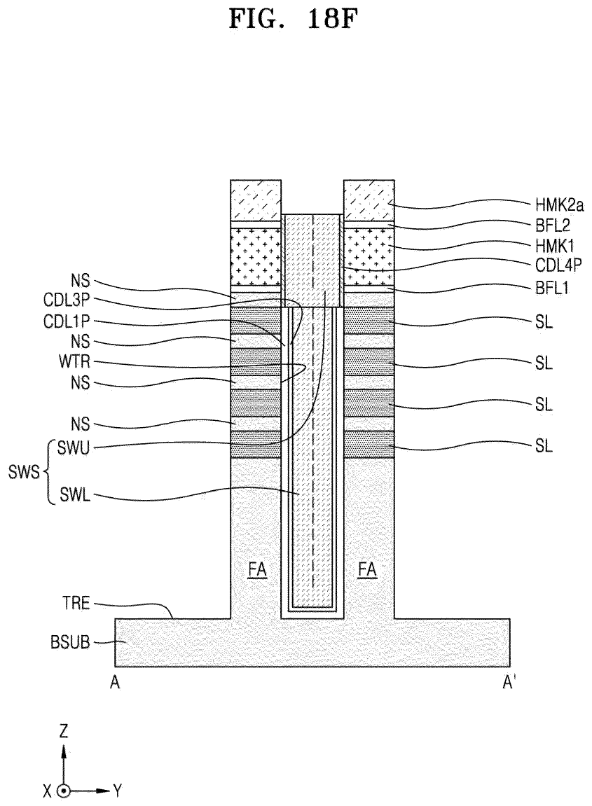

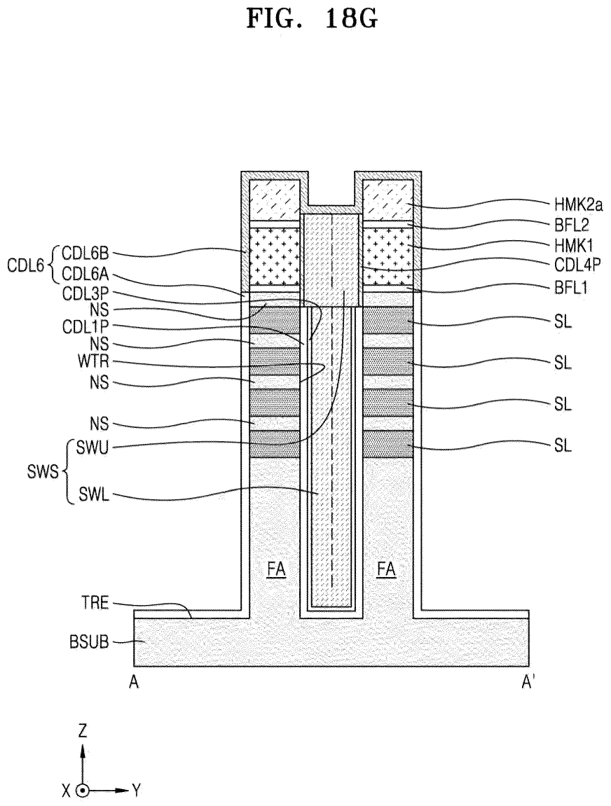

FIGS. 18A, 18B, 18C, 18D, 18E, 18F, and 18G are vertical cross-sectional view for describing a method of manufacturing an integrated circuit device, according to some embodiments. In detail, FIGS. 18A, 18B, 18C, 18D, 18E, 18F, and 18G are vertical cross-sectional views taken along line A-A′ of FIG. 1.

Referring to FIGS. 2G and 18A together, a portion of the third material layer CDL3 and a portion of the first material layer CDL1 may be removed. A (remaining) portion of the third material layer CDL3 may remain as the first insulating pattern CDL3P, and a (remaining) portion of the first material layer CDL1 may remain as the second insulating pattern CDL1P.

After the first insulating pattern CDL3P and the second insulating pattern CDLIP are formed, the fourth material layer CDL4 on (e.g., covering or overlapping) an exposed surface may be formed. The fourth material layer CDL4 may include (e.g., may be formed of) an insulating material. For example, the fourth material layer CDL4 may include (e.g., may be formed of) silicon carbonate.

In some embodiments, instead of a stacked structure of the buffer layer BFL and the hard mask pattern HMK of FIG. 2G, a stacked structure of the first buffer layer BFL1, the first hard mask pattern HMK1, the second buffer layer BFL2, and a second hard mask pattern HMK2a may be formed on a stacked structure of the plurality of sacrificial layers SL and the plurality of nanosheets NS. In some embodiments, the first buffer layer BFL1 and the second buffer layer BFL2 may include (e.g., may be formed of) the same material. The first hard mask pattern HMK1 and the second hard mask pattern HMK2a may include (e.g., may be formed of) different materials. For example, the first hard mask pattern HMK1 and the second hard mask pattern HMK2a may include (e.g., may be formed of) insulating materials having different carbon atom contents.

Referring to FIGS. 18A and 18B together, portions of the fourth material layer CDL4 on (e.g., covering or overlapping in the vertical direction) upper surfaces (e.g., top surfaces) of the base substrate layer BSUB, the second hard mask pattern HMK2a, the first insulating pattern CDL3P, the second insulating pattern CDLIP, and the lower sheet separation wall SWL may be removed. For example, the portions of the fourth material layer CDL4 may be removed by performing an etch-back process.

Referring to FIG. 18C, the preliminary upper separation layer SWUP on (e.g., covering or overlapping) the fourth material layer CDL4, the second hard mask pattern HMK2a, and the lower sheet separation wall SWL and in (at least partially filling) an upper portion of the separation recess WTR may be formed. The preliminary upper separation layer SWUP may directly contact the upper surface (e.g., the top surface) of the lower sheet separation wall SWL. The preliminary upper separation layer SWUP may completely fill the separation recess WTR but may only partially fill the plurality of trenches TRE. For example, the preliminary upper separation layer SWUP may include (e.g., may be formed of) silicon nitride.

Referring to FIGS. 18C and 18D, the upper sheet separation wall SWU may be formed by removing a portion of the preliminary upper separation layer SWUP. The upper sheet separation wall SWU may be in (e.g., may fill) a part of the upper portion of the separation recess WTR. The upper sheet separation wall SWU and the lower sheet separation wall SWL may constitute the sheet separation wall SWS. A lower surface (e.g., a bottom surface) of the upper sheet separation wall SWU and the upper surface (e.g., the top surface) of the lower sheet separation wall SWL may contact each other.

Referring to FIGS. 18D and 18E, a physical property of a portion of the fourth material layer CDL4 exposed to the outside may be changed to form the fifth material layer CDL5. A remaining (an unchanged) portion of the fourth material layer CDL4 may remain as the sheet barrier pattern CDL4P. The sheet barrier pattern CDL4P may be on (e.g., may cover or overlap) a side surface of the upper sheet separation wall SWU. One side surface of a stacked structure of the first buffer layer BFL1, the first hard mask pattern HMK1, the second buffer layer BFL2, and the second hard mask pattern HMK2a in the second horizontal direction (e.g., Y direction) may be covered (or overlapped) by a portion of the fifth material layer CDL5, an upper portion of the other side surface of the stacked structure may be covered (or overlapped) by another portion of the fifth material layer CDL5, and a lower portion of the other side surface of the stacked structure may be covered (or overlapped) by the sheet barrier pattern CDL4P. For example, the stacked structure of the first buffer layer BFL1, the first hard mask pattern HMK1, the second buffer layer BFL2, and the second hard mask pattern HMK2a may be between the fifth material layer CDL5 and the sheet barrier pattern CDL4P in the second horizontal direction (e.g., Y direction).

Referring to FIGS. 18E and 18F, the fifth material layer CDL5 may be removed. The sheet barrier pattern CDL4P may be remained (maintained) without being removed.

Referring to FIGS. 18E, 18F, and 18G together, the sixth material layer CDL6 on (e.g., conformally covering or overlapping) a surface exposed after removing the fifth material layer CDL5 may be formed. The sixth material layer CDL6 may include (e.g., may be formed of) a semiconductor material. The sixth material layer CDL6 may include the first layer CDL6A and the second layer CDL6B. The first layer CDL6A and the second layer CDL6B may have different physical properties.

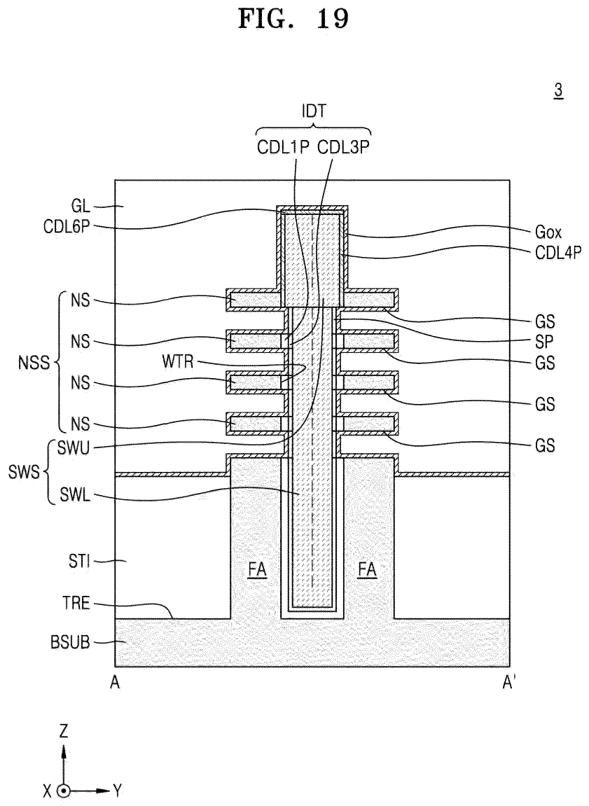

FIG. 19 is a vertical cross-sectional view illustrating an integrated circuit device, according to some embodiments. In detail, FIG. 19 is a vertical cross-sectional view taken along line A-A′ of FIG. 1.

Referring to FIG. 19, after the sixth material layer CDL6 shown in FIG. 18G is formed, an integrated circuit device 3 may be formed with reference to FIGS. 2N, 2O, 2P, 2Q, 2R, 2S, 2T, 2U, 3A, 3B, 3C, 4A, 4B, 5A, 5B, 6A, 6B, 7A, 7B, 8A, 8B, 9A, 9B, 10A, 10B, 11A, 11B, 12A, 12B, 13A, 13B, 14A, and 14B. The sheet barrier pattern CDL4P included in the integrated circuit device 3 may be (e.g., may cover or overlap) a side surface of the upper sheet separation wall SWU. The sheet barrier pattern CDL4P may not be located between the lower sheet separation wall SWL and the upper sheet separation wall SWU of the sheet separation wall SWS included in the integrated circuit device 3. The lower sheet separation wall SWL and the upper sheet separation wall SWU of the sheet separation wall SWS may directly contact each other.

In some embodiments, the indent spacer IDT may not be located between the sheet separation wall SWS and the uppermost nanosheet NS from among the plurality of nanosheets NS but may be located between the sheet separation wall SWS and the remaining nanosheets NS (lower than the uppermost nanosheet NS from among the plurality of nanosheets NS).

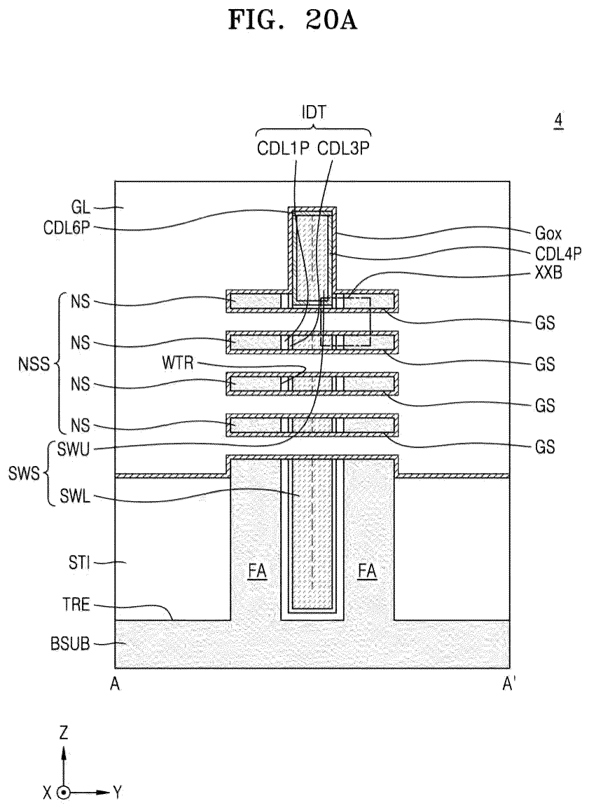

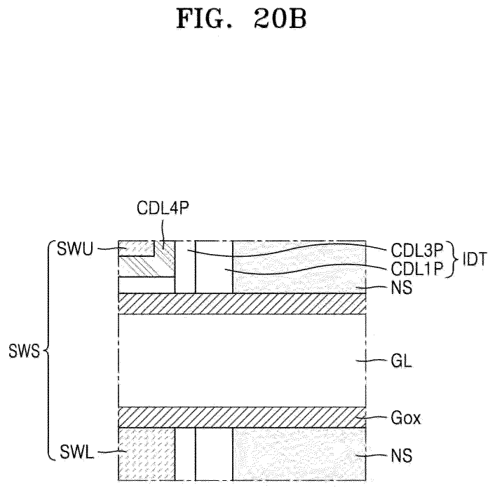

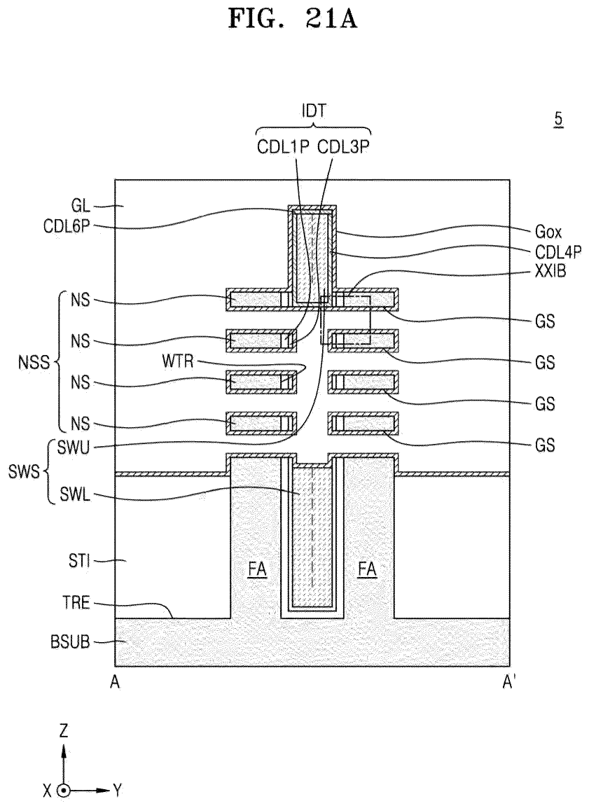

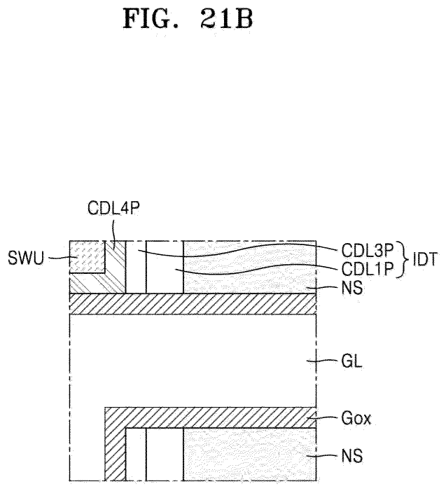

FIGS. 20A and 20B and 21A and 21B are vertical cross-sectional views illustrating an integrated circuit device, according to some embodiments. In detail, FIGS. 20A and 21A are vertical cross-sectional views taken along line A-A′ of FIG. 1. FIG. 20B is an enlarged view illustrating a portion XXB of FIG. 20A. FIG. 21B is an enlarged view illustrating a portion XXIB of FIG. 21A.

Referring to FIGS. 20A and 20B together, the gate insulating layer Gox included in an integrated circuit device 4 and the gate electrode GL on (e.g., covering or overlapping) the gate insulating layer Gox may pass through the sheet separation wall SWS to connect one pair of gate spaces GS corresponding to each other in the second horizontal direction (e.g., Y direction). For example, the gate insulating layer Gox and the gate electrode GL may pass through the lower sheet separation wall SWL but may not pass through the upper sheet separation wall SWU. For example, portions of the lower sheet separation wall SWL may be separated from each other by the gate insulating layer Gox and the gate electrode GL therebetween (in the vertical direction (e.g., Z direction)).

In the integrated circuit device 4 according to the inventive concept, because the sheet separation wall SWS includes the lower sheet separation wall SWL and the upper sheet separation wall SWU formed through a separate process, the gate insulating layer Gox and the gate electrode GL may pass through (only) the lower sheet separation wall SWL. Accordingly, the gate electrode GL may function as a shared gate shared by one pair of nanosheet stacked structures NSS adjacent to each other in the second horizontal direction (e.g., Y direction).

Referring to FIGS. 21A and 21B, the gate insulating layer Gox included in an integrated circuit device 5 and the gate electrode GL on (e.g., covering or overlapping) the gate insulating layer Gox may pass through the sheet separation wall SWS to connect the plurality of gate spaces GS of one pair of nanosheet stacked structures NSS adjacent to each other. For example, the gate insulating layer Gox and the gate electrode GL may pass through the lower sheet separation wall SWL but may not pass through the upper sheet separation wall SWU. For example, portions of the lower sheet separation wall SWL may be separated from each other by the gate insulating layer Gox and the gate electrode GL therebetween (in the vertical direction (e.g., Z direction) and/or the second horizontal direction (e.g., Y direction)).

In the second horizontal direction (e.g., Y direction), the lower sheet separation wall SWL may not be located between one pair of nanosheet stacked structures NSS adjacent to each other, but the lower sheet separation wall SWL may be located between one pair of fin-type active areas FA adjacent to each other in the second horizontal direction (e.g., Y direction).

In the integrated circuit device 5 according to the inventive concept, because the sheet separation wall SWS includes the lower sheet separation wall SWL and the upper sheet separation wall SWU formed through a separate process, after the plurality of gate spaces GS are formed, an entire portion of the lower sheet separation wall SWL located between one pair of nanosheet stacked structures NSS adjacent to each other in the second horizontal direction (e.g., Y direction) may be removed so that the gate insulating layer Gox and the gate electrode GL filling the plurality of gate spaces GS of the pair of nanosheet stacked structures NSS adjacent to each other are connected to each other. The gate electrode GL may function as a shared gate shared by the pair of nanosheet stacked structures NSS adjacent to each other in the second horizontal direction (e.g., Y direction).

Accordingly, in the integrated circuit device 5 according to the inventive concept, because a uniform bias may be applied to each of the plurality of nanosheets NS included in each of the pair of nanosheet stacked structures NSS, operational reliability may be ensured.

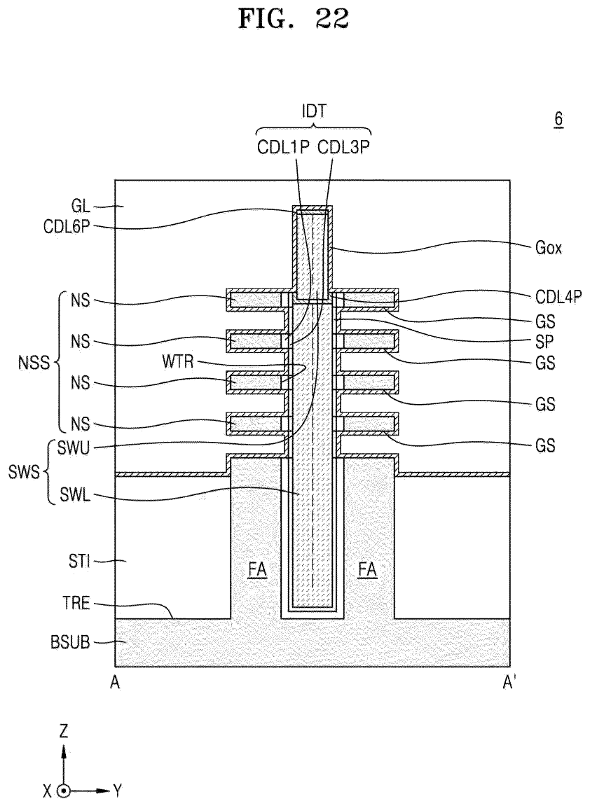

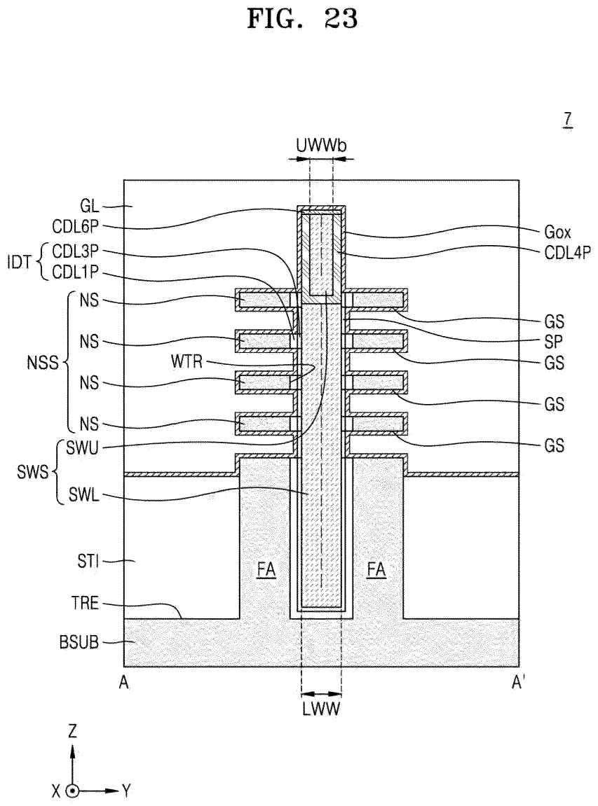

FIGS. 22 and 23 are vertical cross-sectional view illustrating an integrated circuit device, according to some embodiments. In detail, FIGS. 22 and 23 are vertical cross-sectional views taken along line A-A′ of FIG. 1.

Referring to FIG. 22, the sheet barrier pattern CDL4P included in an integrated circuit device 6 may be on (e.g., cover or overlap) a lower surface (e.g., a bottom surface) of the upper sheet separation wall SWU but may not be on (e.g., may not cover) at least a portion of a side surface of the upper sheet separation wall SWU.

Referring to FIGS. 2T, 2U, and 22 together, when the eighth material layer CDL8 is formed after removing a portion of the sheet barrier pattern CDL4P exposed to the outside, the sheet barrier pattern CDL4P may not be on (e.g., may not cover) at least a portion of a side surface of the upper sheet separation wall SWU.

In some embodiments, an uppermost end of the sheet barrier pattern CDL4P may be located at the same vertical level as (e.g., may be coplanar with) an upper surface (e.g., a top surface) of the uppermost nanosheet NS from among the plurality of nanosheets NS. For example, the sheet barrier pattern CDL4P may be on (e.g., may cover or overlap) the lower surface (e.g., the bottom surface) of the upper sheet separation wall SWU, may be on (e.g., may cover) only a lower portion of the side surface of the upper sheet separation wall SWU, and may not be on (e.g., may not cover) a remaining upper portion of the side surface of the upper sheet separation wall SWU.

Referring to FIG. 23, the lower sheet separation wall SWL of the sheet separation wall SWS included in an integrated circuit device 7 may have the lower width LWW (in the second horizontal direction (e.g., Y direction)), and the upper sheet separation wall SWU of the sheet separation wall SWS may have an upper width UWWb (in the second horizontal direction (e.g., Y direction)). For example, the lower width LWW may be greater than an upper width UWWb by a thickness of the sheet barrier pattern CDL4P. The upper width UWWb of the upper sheet separation wall SWU included in the integrated circuit device 7 may be less than the upper width

UWW of the upper sheet separation wall SWU included in the integrated circuit device 1 of FIG. 15A.

In a process of forming the fourth material layer CDL4 shown in FIG. 2H, when the fourth material layer CDL4 is formed relatively thick, the upper width UWWb of the upper sheet separation wall SWU may be formed relatively narrow.

While the inventive concept has been particularly shown and described with reference to embodiments thereof, it will be understood that various changes in form and details may be made therein without departing from the scope of the following claims.

What is claimed is:

1. An integrated circuit device comprising:
a base substrate layer comprising a pair of fin-type active areas spaced apart from each other with a separation recess therebetween in a first direction and protruding in a second direction;
a sheet separation wall comprising a lower sheet separation wall and an upper sheet separation wall on the lower sheet separation wall, the sheet separation wall extending in a third direction along the separation recess;
a sheet barrier pattern on a lower surface and/or at least a portion of a side surface of the upper sheet separation wall;
a pair of nanosheet stacked structures on the pair of fin-type active areas and spaced apart from each other in the first direction with the separation recess and the sheet separation wall therebetween, each of the pair of nanosheet stacked structures comprising a plurality of nanosheets;
a gate electrode on the pair of fin-type active areas and the pair of nanosheet stacked structures and extending in the first direction;
a plurality of indent spacers between the plurality of nanosheets and the sheet separation wall; and
a plurality of spacer layers between the gate electrode and the sheet separation wall,
wherein the first direction is parallel with a lower surface of the base substrate layer,
wherein the second direction is perpendicular to the lower surface of the base substrate layer, and
wherein the third direction is parallel with the lower surface of the base substrate layer and intersects with the first direction.

2. The integrated circuit device of claim 1, wherein, in the first direction, a width of the upper sheet separation wall and a width of the lower sheet separation wall are different from each other.

3. The integrated circuit device of claim 1, wherein, on a side surface of the sheet separation wall, a thickness of each of the plurality of indent spacers in the first direction is greater than a thickness of each of the plurality of spacer layers in the first direction.

4. The integrated circuit device of claim 1, wherein the upper sheet separation wall and the lower sheet separation wall are spaced apart from each other in the second direction, and wherein the sheet barrier pattern is between the lower surface of the upper sheet separation wall and an upper surface of the lower sheet separation wall.

5. The integrated circuit device of claim 4, wherein the sheet barrier pattern is on the lower surface of the upper sheet separation wall and at least a lower portion of the side surface of the upper sheet separation wall.

6. The integrated circuit device of claim 1, wherein an end portion of the gate electrode facing a side surface of the sheet separation wall is closer to the side surface of the sheet separation wall than respective end portions of each of the plurality of nanosheets facing the side surface of the sheet separation wall in the first direction.

7. The integrated circuit device of claim 1, wherein the lower surface of the upper sheet separation wall and an upper surface of the lower sheet separation wall contact each other, and
wherein the sheet barrier pattern is on the side surface of the upper sheet separation wall.

8. The integrated circuit device of claim 1, wherein each of the plurality of indent spacers includes a stacked structure comprising a first insulating pattern on a side surface of the sheet separation wall and a second insulating pattern on the first insulating pattern.

9. The integrated circuit device of claim 1, wherein an uppermost end of the upper sheet separation wall protrudes in the second direction from an upper surface of an uppermost nanosheet from among the plurality of nanosheets.

10. The integrated circuit device of claim 1, wherein an uppermost end of the lower sheet separation wall is farther than a lower surface of an uppermost nanosheet from among the plurality of nanosheets from the lower surface of the base substrate layer in the second direction.

11. The integrated circuit device of claim 1, wherein the plurality of indent spacers are between nanosheets that are lower than an uppermost nanosheet from among the plurality of nanosheets and the sheet separation wall.

12. An integrated circuit device comprising:
a base substrate layer comprising a pair of fin-type active areas spaced apart from each other with a separation recess therebetween in a first direction and protruding in a second direction;
a sheet separation wall extending in a third direction along the separation recess and comprising a lower sheet separation wall and an upper sheet separation wall on the lower sheet separation wall, wherein a width of the lower sheet separation wall is greater than a width of the upper sheet separation wall in the first direction;
a sheet barrier pattern between a lower surface of the upper sheet separation wall and an upper surface of the lower sheet separation wall;
a pair of nanosheet stacked structures on the pair of fin-type active areas and spaced apart from each other in the first direction with the separation recess and the sheet separation wall therebetween, each of the pair of nanosheet stacked structures comprising a plurality of nanosheets;
a pair of source/drain regions on the pair of fin-type active areas and electrically connected to the plurality of nanosheets included in the pair of nanosheet stacked structures;
a gate electrode on the pair of fin-type active areas and the pair of nanosheet stacked structures and extending in the first direction;
a plurality of indent spacers between the plurality of nanosheets and the sheet separation wall; and
a plurality of spacer layers between the gate electrode and the sheet separation wall,
wherein the first direction is parallel with a lower surface of the base substrate layer,
wherein the second direction is perpendicular to the lower surface of the base substrate layer, and
wherein the third direction is parallel with the lower surface of the base substrate layer and intersects with the first direction.

13. The integrated circuit device of claim 12, wherein the upper sheet separation wall and the lower sheet separation wall are spaced apart from each other in the second direction, and wherein the sheet barrier pattern extends between the lower surface of the upper sheet separation wall and the upper surface of the lower sheet separation wall to be on at least a portion of a side surface of the upper sheet separation wall.

14. The integrated circuit device of claim 13, wherein an uppermost end of the sheet barrier pattern and an uppermost end of the upper sheet separation wall are coplanar with each other.

15. The integrated circuit device of claim 12, further comprising:
a gate insulating layer between the gate electrode and the plurality of nanosheets included in the pair of nanosheet stacked structures and between the gate electrode and the pair of fin-type active areas; and
a cover pattern on an upper surface of the upper sheet separation wall and between the upper sheet separation wall and the gate insulating layer.

16. The integrated circuit device of claim 12, wherein the pair of nanosheet stacked structures are spaced apart from each other in the first direction by the upper sheet separation wall,
wherein the pair of nanosheet stacked structures are spaced apart from each other in the first direction by the lower sheet separation wall, and
wherein the pair of source/drain regions are spaced apart from each other in the first direction by the lower sheet separation wall.

17. The integrated circuit device of claim 16, wherein an uppermost end of the lower sheet separation wall between the pair of source/drain regions is closer than an uppermost end of each of the pair of source/drain regions to the lower surface of the base substrate layer.

18. The integrated circuit device of claim 12, wherein, on a side surface of the sheet separation wall, a thickness of each of the plurality of indent spacers in the first direction is greater than a thickness of each of the plurality of spacer layers in the first direction, and
wherein an end portion of the gate electrode facing the side surface of the sheet separation wall is closer to the side surface of the sheet separation wall than respective end portions of each of the plurality of nanosheets facing the side surface of the sheet separation wall in the first direction.

19. An integrated circuit device comprising:
a base substrate layer comprising a pair of fin-type active areas spaced apart from each other with a separation recess therebetween in a first direction and protruding in a second direction;
a sheet separation wall comprising a lower sheet separation wall and an upper sheet separation wall on the lower sheet separation wall, wherein the lower sheet separation wall and the upper sheet separation wall is spaced apart from each other in the second direction, and the sheet separation wall extends in a third direction along the separation recess;
a sheet barrier pattern on a lower surface and a side surface of the upper sheet separation wall and comprising a material different from a material in the sheet separation wall;
a pair of nanosheet stacked structures on the pair of fin-type active areas and spaced apart from each other in the first direction with the separation recess and the sheet separation wall therebetween, each of the pair of nanosheet stacked structures comprising a plurality of nanosheets;
source/drain regions on the pair of fin-type active areas and electrically connected to the plurality of nanosheets included in the pair of nanosheet stacked structures;
a gate electrode on the pair of fin-type active areas and the pair of nanosheet stacked structures and extending in the first direction;
a gate insulating layer between the gate electrode and the plurality of nanosheets included in the pair of nanosheet stacked structures and between the gate electrode and the pair of fin-type active areas;
a plurality of indent spacers between the plurality of nanosheets and the sheet separation wall; and
a plurality of spacer layers between the gate electrode and the sheet separation wall, wherein a thickness of each of the plurality of spacer layers on a side surface of the sheet separation wall in the first direction is less than a thickness of each of the plurality of indent spacers in the first direction,
wherein, in the first direction, a width of the upper sheet separation wall is less than a width of the lower sheet separation wall,
wherein the first direction is parallel with a lower surface of the base substrate layer,
wherein the second direction is perpendicular to the lower surface of the base substrate layer, and
wherein the third direction is parallel with the lower surface of the base substrate layer and intersects with the first direction.

20. The integrated circuit device of claim 19, wherein an uppermost end of the upper sheet separation wall is farther than an upper surface of an uppermost nanosheet from among the plurality of nanosheets from the lower surface of the base substrate layer,
wherein an uppermost end of the lower sheet separation wall is closer than the upper surface of the uppermost nanosheet from among the plurality of nanosheets to the lower surface of the base substrate layer, and
wherein the uppermost end of the lower sheet separation wall is coplanar with or farther than a lower surface of the uppermost nanosheet from among the plurality of nanosheets from the lower surface of the base substrate layer.
